(19) United States
(12) Patent Application Publication
(10) Pub. No.: US 2026/0157058 A1
(43) Pub. Date: Jun. 4, 2026

(54) Display Substrate, Manufacturing Method Therefor, and Display Apparatus

(71) Applicants: Chengdu BOE Optoelectronics Technology Co., Ltd., Chengdu, Sichuan (CN); BOE Technology Group Co., Ltd., Beijing (CN)

(72) Inventors: Tiaomei ZHANG, Beijing (CN); Lang LIU, Beijing (CN); Hongbo MA, Beijing (CN); Mingkun YANG, Beijing (CN); Zhen LIU, Beijing (CN)

(21) Appl. No.: 18/705,533

(22) PCT Filed: Apr. 27, 2023
(86) PCT No.: PCT/CN2023/091344

§ 371 Date: Apr. 27, 2024

(51) Int. Cl. H10K 59/131; H10K 59/12; H10K 59/126

(52) U.S. Cl. CPC H10K 59/131; H10K 59/1201; H10K 59/126

(57) ABSTRACT

Disclosed are a display substrate, a manufacturing method therefor, and a display apparatus. The display substrate includes a plurality of circuit units, at least one circuit unit includes a pixel drive circuit, the pixel drive circuit includes, at least, a first storage capacitor and a second storage capacitor, the first storage capacitor includes at least two first capacitor plates, orthographic projections of the two first capacitor plates on a substrate are overlapped, at least partially, with each other, the second storage capacitor includes at least two second capacitor plates, orthographic projections of the two second capacitor plates on the substrate are overlapped, at least partially, with each other.

### CROSS-REFERENCE TO RELATED APPLICATION

The present application is a U.S. National Phase Entry of International Application No. PCT/CN2023/091344 having an international filing date of Apr. 27, 2023. The above-identified application is hereby incorporated by reference.

### TECHNICAL FIELD

The present disclosure relates to, but is not limited to, the field of display technologies, and particularly to a display substrate, a manufacturing method therefor, and a display apparatus.

### BACKGROUND

Organic Light Emitting Diodes (OLEDs) and Quantum dot Light Emitting Diodes (QLEDs) are active light emitting display devices and have advantages such as self-luminescence, wide viewing angle, high contrast ratio, low power consumption, extremely high response speed, lightness and thinness, flexibility, and low cost. With constant development of display technologies, a flexible display that uses an OLED or a QLED as a light emitting device and performs signal control by a Thin Film Transistor (TFT for short) has become the mainstream product in the field of display at present.

### SUMMARY

The following is a summary of subject matters described herein in detail. This summary is not intended to limit the protection scope of claims.

In one aspect, the present disclosure provides a display substrate, including a plurality of circuit units, wherein at least one circuit unit includes a pixel drive circuit, the pixel drive circuit includes, at least, a first storage capacitor and a second storage capacitor, the first storage capacitor includes at least two first capacitor plates, orthographic projections of the two first capacitor plates on a substrate are overlapped, at least partially, with each other, the second storage capacitor includes at least two second capacitor plates, orthographic projections of the two second capacitor plates on the substrate are overlapped, at least partially, with each other; in a plane perpendicular to the display substrate, the display substrate includes a plurality of conductive layers, a first capacitor plate in the first storage capacitor and a second capacitor plate in the second storage capacitor are disposed in a same conductive layer, another first capacitor plate in the first storage capacitor and another second capacitor plate in the second storage capacitor are disposed in a same conductive layer, and one first capacitor plate in the first storage capacitor and one second capacitor plate in the second storage capacitor are connected with each other.

In an exemplary implementation, the plurality of conductive layers include, at least, a first conductive layer and a second conductive layer disposed sequentially on the substrate; the at least two first capacitor plates include a first plate disposed in the first conductive layer, and a third plate disposed in the second conductive layer, an orthographic projection of the first plate on the substrate is overlapped, at least partially, with an orthographic projection of the third plate on the substrate; the at least two second capacitor plates include a second plate disposed in the first conductive layer, a fourth plate disposed in the second conductive layer, an orthographic projection of the second plate on the substrate is overlapped, at least partially, with an orthographic projection of the fourth plate on the substrate, and the third plate is connected with the fourth plate.

In an exemplary implementation, the third plate of the first storage capacitor and the fourth plate of the second storage capacitor are connected with each other to form an integral structure.

In an exemplary implementation, the pixel drive circuit further includes a first initialization transistor, a compensation transistor, a data writing transistor, and a first reference transistor, which have a double gate structure, wherein a first electrode of the first initialization transistor is connected with a first initial signal line, a second electrode of the first initialization transistor is connected with a first electrode of the data writing transistor and the first plate, respectively, a first electrode of the data writing transistor is connected with the data signal line, a second electrode of the data writing transistor is connected with a second electrode of the first reference transistor, the third plate and the fourth plate, respectively, and a first electrode of the first reference transistor is connected with a first reference signal line.

In an exemplary implementation, at least one circuit unit further includes a first shield electrode whose orthographic projection on the substrate is overlapped, at least partially, with an orthographic projection of a node between two gate electrodes of the first initialization transistor on the substrate, and the orthographic projection of the first shield electrode on the substrate is overlapped, at least partially, with an orthographic projection of a node between two gate electrodes of the compensation transistor on the substrate.

In an exemplary implementation, the display substrate further includes at least one first power supply connection line extending along a first direction, and at least one first power line extending along a second direction, the first direction intersects with the second direction; the first power line and the first power supply connection line are disposed in different conductive layers, the first power line and the first power supply connection line are connected through a via to form a mesh structure for transmitting a first power supply signal, and the first shield electrode is connected with the first power supply connection line.

In an exemplary implementation, the first shield electrode includes a first extension section and a first shield section; a shape of the first extension section is a shape of strip extending along the second direction, and a shape of the first shield section is a shape of strip extending along the first direction; a first end of the first extension section is connected with the first power supply connection line, and a second end of the first extension section is connected with the first shield section; the first shield section includes a first shield end and a second shield end, an orthographic projection of the first shield end on the substrate is overlapped, at least partially, with the orthographic projection of the node between the two gate electrodes of the first initialization transistor in the circuit unit on the substrate, and an orthographic projection of the second shield end on the substrate is overlapped, at least partially, with an orthographic projection of a node between two gate electrodes of a compensation transistor in an adjacent circuit unit on the substrate.

In an exemplary implementation, the first shield electrode and the first power supply connection line are connected with each other to form an integral structure.

In an exemplary implementation, an orthographic projection of the first power supply connection line on the substrate is overlapped, at least partially, with the orthographic projection of the fourth plate on the substrate.

In an exemplary implementation, the display substrate further includes at least one second power supply connection line extending along a first direction, and at least one second power line extending along a second direction, the first direction intersects with the second direction; the second power line and the second power supply connection line are disposed in different conductive layers, the second power line and the second power supply connection line are connected through a via to form a mesh structure for transmitting a second power supply signal, and the first shield electrode is connected with the second power supply connection line.

In an exemplary implementation, the first shield electrode includes a first extension section and a first shield section; a shape of the first extension section is a shape of strip extending along the second direction, and a shape of the first shield section is a shape of strip extending along the first direction; a first end of the first extension section is connected with the second power supply connection line, and a second end of the first extension section is connected with the first shield section; the first shield section includes a first shield end and a second shield end, an orthographic projection of the first shield end on the substrate is overlapped, at least partially, with the orthographic projection of the node between the two gate electrodes of the first initialization transistor in the circuit unit on the substrate, and an orthographic projection of the second shield end on the substrate is overlapped, at least partially, with an orthographic projection of a node between two gate electrodes of a compensation transistor in an adjacent circuit unit on the substrate.

In an exemplary embodiment, the first shield electrode and the second power supply connection line are connected with each other to form an integral structure.

In an exemplary implementation, an orthographic projection of the second power supply connection line on the substrate is overlapped, at least partially, with the orthographic projection of the third plate on the substrate.

In an exemplary implementation, at least one circuit unit further includes a second shield electrode, an orthographic projection of the second shield electrode on the substrate is overlapped, at least partially, with an orthographic projection of a node between two gate electrodes of the data writing transistor on the substrate.

In an exemplary implementation, at least one circuit unit further includes a third shield electrode, an orthographic projection of the third shield electrode on the substrate is overlapped, at least partially, with an orthographic projection of a node between two gate electrodes of the first reference transistor on the substrate.

In an exemplary implementation, the display substrate further includes at least one reference signal connection line extending along the first direction, and at least one reference signal line extending along the second direction, the first direction intersects with the second direction; the reference signal line and the reference signal connection line are disposed in different conductive layers, and the reference signal connection line is connected with the reference signal line through a via to form a mesh structure for transmitting a reference signal.

In an exemplary implementation, the display substrate further includes at least one initial signal line extending along the first direction and at least one initial connection line extending along the second direction, the first direction intersects with the second direction; the initial signal line and the initial connection line are disposed in different conductive layers, and the initial connection line is connected with the initial signal line through a via to form a mesh structure for transmitting an initial signal.

In another aspect, the present disclosure further provides a display apparatus, including the display substrate described above.

In still another aspect, the present disclosure further provides a method for manufacturing a display substrate, wherein the display substrate includes a plurality of circuit units, wherein at least one circuit unit includes a pixel drive circuit, the pixel drive circuit includes, at least, a first storage capacitor and a second storage capacitor, the first storage capacitor includes at least two first capacitor plates, orthographic projections of the two first capacitor plates on a substrate are overlapped, at least partially, with each other, the second storage capacitor includes at least two second capacitor plates, orthographic projections of the two second capacitor plates on the substrate are overlapped, at least partially, with each other; the manufacturing method includes: forming a plurality of conductive layers on the substrate, one first capacitor plate in the first storage capacitor and one second capacitor plate in the second storage capacitor are disposed in a same conductive layer, the other first capacitor plate in the first storage capacitor and the other second capacitor plate in the second storage capacitor are disposed in a same conductive layer, and one of the first capacitor plates in the first storage capacitor and one of the second capacitor plates in the second storage capacitor are connected with each other.

Other aspects of the present disclosure may be comprehended after the drawings and the detailed descriptions are read and understood.

### BRIEF DESCRIPTION OF DRAWINGS

Accompany drawings are used to provide further understanding of technical solution of the present disclosure, and form a part of the description. The accompany drawings and embodiments of the present disclosure are adopted to explain the technical solution of the present disclosure, and do not form limitations on the technical solution of the present disclosure.

FIG. 1 is a schematic diagram of a structure of a display apparatus.

FIG. 2 illustrates a schematic diagram of a planar structure of a display substrate;

FIG. 3 illustrates a schematic diagram of a sectional structure of a display substrate;

FIG. 4 is an equivalent circuit diagram of a pixel drive circuit according to an exemplary embodiment of the present disclosure.

FIG. 5 is a schematic diagram of a planar structure of a display substrate according to an exemplary embodiment of the present disclosure.

FIG. 6 is a schematic diagram of a regional structure of the first storage capacitor and the second storage capacitor in FIG. 5.

FIG. 7 is a schematic diagram of a display substrate after a pattern of a semiconductor layer is formed according to the present disclosure.

FIG. 8A and FIG. 8B are schematic diagrams of a display substrate after a pattern of a first conductive layer is formed according to the present disclosure.

FIG. 9A and FIG. 9B are schematic diagrams of a display substrate after a pattern of a second conductive layer is formed according to the present disclosure.

FIG. 10 is a schematic diagram of a display substrate after a pattern of a fourth insulation layer is formed according to the present disclosure.

FIG. 11A and FIG. 11B are schematic diagrams of a display substrate after a pattern of a third conductive layer is formed according to the present disclosure.

FIG. 12 is a schematic diagram of a display substrate after a pattern of a fifth insulation layer is formed according to the present disclosure.

FIG. 13A and FIG. 13B are schematic diagrams of a display substrate after a pattern of a fourth conductive layer is formed according to the present disclosure.

FIG. 14 illustrates a schematic diagram of a planar structure of another display substrate according to an exemplary embodiment of the present disclosure.

FIG. 15 is a schematic diagram of a regional structure of the first storage capacitor and the second storage capacitor in FIG. 14.

FIG. 16A and FIG. 16B are schematic diagrams of another display substrate after a pattern of a third conductive layer is formed according to the present disclosure;

FIG. 17 is a schematic diagram of another display substrate after a pattern of a fifth insulation layer is formed according to the present disclosure.

FIG. 18A and FIG. 18B are schematic diagrams of another display substrate after a pattern of a fourth conductive layer is formed according to the present disclosure.

### DESCRIPTION OF REFERENCE NUMBERS

| | | |
|---|---|---|
| 10-first active | 11-first active layer; | 12-second active |
| connection line; | | layer; |
| 13-third active layer; | 14-fourth active layer; | 15-fifth active layer; |
| 16-sixth active layer; | 17-seventh active layer; | 18- eighth active layer; |
| 19-ninth active layer; | 20-second active | 21-first gate |
| | connection line; | electrode; |
| 22-second gate | 24-fourth gate | 25-fifth gate |
| electrode; | electrode; | electrode; |
| 26-sixth gate | 29-ninth gate | 31-first light emitting |
| electrode; | electrode; | signal line; |
| 31-1-first light | 32-second light | 32-1-second light |
| emitting | emitting | emitting connection |
| connection block; | signal line; | block; |
| 33-repair line; | 36-first shield | 36-1-first extension |
| | electrode; | section; |
| 36-2-first shield | 37-second shield | 38-third shield |
| section; | electrode; | electrode; |
| 41-first connection | 42-second connection | 43-third connection |
| electrode; | electrode; | electrode; |
| 44-fourth connection | 45-fifth connection | 46-sixth connection |
| electrode; | electrode; | electrode; |
| 47-seventh connection | 48-eighth connection | 49-ninth connection |
| electrode; | electrode; | electrode; |
| 51-first power line; | 51-1-power supply | 52-second power line; |
| | shield; | |
| 53-data signal line; | 54-reference signal | 55-anode connection |
| | connection line; | electrode; |
| 56-second initial | 61-first scan signal | 62-second scan signal |
| connection line; | line; | line |
| 63-third scan signal | 64-fourth scan signal | 65-fifth scan signal |
| line; | line; | line; |
| 68-first power supply | 68-1-first power | 68-2-second power |
| connection line; | connection block; | supply connection |
| | | block; |
| 69-second power | 69-1-third power | 71-first plate; |
| supply connection | connection block; | |
| line; | | |
| 72-second plate; | 1-protrusion; | 2-plate connection |
| | | line; |
| 73-third plate; | 74-fourth plate; | 74-2-plate connection |
| | | block; |
| 75-first opening; | 76-second opening; | 81-first initial |
| | | signal line; |
| 81-1-first initial | 82-second initial | 82-1-second initial |
| connection block; | signal line; | connection block; |
| 91-first reference | 91-1-first reference | 92-second reference |
| signal line; | connection block; | signal line; |
| 92-1-second reference | 101-substrate; | 102-drive circuit layer; |
| connection block; | | |
| 103-light emitting | 104-encapsulation | |
| structure layer; | structure layer. | |

### DETAILED DESCRIPTION

To make the objectives, technical solutions, and advantages of the present disclosure clearer, the embodiments of the present disclosure will be described in detail below with reference to the accompany drawings. It is to be noted that implementations may be implemented in multiple different forms. Those of ordinary skills in the art can easily understand such a fact that implementations and contents may be transformed into various forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

Scales of the drawings in the present disclosure may be used as a reference in actual processes, but are not limited thereto. For example, a width-length ratio of a channel, a thickness and spacing of each film layer, and a width and spacing of each signal line may be adjusted according to actual needs. A quantity of pixels in a display substrate and a quantity of sub-pixels in each pixel are not limited to numbers shown in the drawings. The drawings described in the present disclosure are schematic structural diagrams only, and one mode of the present disclosure is not limited to shapes, numerical values, or the like shown in the drawings.

Ordinal numerals “first”, “second”, “third”, etc., in the specification are set not to form limits in numbers but only to avoid confusion between composition elements.

In the specification, for convenience, expressions “central”, “above”, “below”, “front”, “back”, “vertical”, “horizontal”, “top”, “bottom”, “inside”, “outside”, etc., indicating orientation or positional relationships are used to illustrate positional relationships between the composition elements, not to indicate or imply that involved devices or elements are required to have specific orientations and be structured and operated with the specific orientations but only to easily and simply describe the present specification, and thus should not be understood as limitations on the present disclosure. The positional relationships between the constituent elements may be changed as appropriate according to a direction according to which each constituent element is described. Therefore, appropriate replacements based on situations are allowed, which is not limited to the expressions in the specification.

In the specification, unless otherwise specified and defined, terms “mounting”, “mutual connection”, and “connection” should be understood in a broad sense. For example, a connection may be fixed connection, or a detachable connection, or an integral connection; it may be a mechanical connection or an electrical connection; it may be a direct connection, or an indirect connection through middleware, or internal communication inside two elements. Those of ordinary skills in the art may understand specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. It is to be noted that in the specification, the channel region refers to a region through which a current mainly flows.

In the specification, a first electrode may be a drain electrode, and a second electrode may be a source electrode. Or, the first electrode may be a source electrode, and the second electrode may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode”, as well as the “source terminal” and the “drain terminal”, are interchangeable in the specification.

In the specification, “electrical connection” includes connection of composition elements through an element with a certain electrical action. An “element with a certain electrical action” is not particularly limited as long as electrical signals between the connected constituent elements may be sent and received. Examples of the “element with the certain electrical action” not only include an electrode and a wiring, but also include a switching element such as a transistor, a resistor, an inductor, a capacitor, another element with various functions, etc.

In the specification, “parallel” refers to a state in which an angle formed by two straight lines is −10° or more and 10° or less, and thus also includes a state in which the angle is −5° or more and 5° or less. In addition, “perpendicular” refers to a state in which an angle formed by two straight lines is 80° or more and 100° or less, and thus also includes a state in which the angle is 85° or more and 95° or less.

In the specification, a “film” and a “layer” are interchangeable. For example, a “conductive layer” may be replaced with a “conductive thin film” sometimes. Similarly, an “insulation film” may be replaced with an “insulation layer” sometimes.

Triangle, rectangle, trapezoid, pentagon, hexagon and the like in this specification are not strictly defined, and they may be approximate triangle, rectangle, trapezoid, pentagon, hexagon and the like. There may be some small deformations caused by tolerance, and there may be chamfer, arc edge, deformation, etc.

In the present disclosure, “about” refers to that a boundary is not defined so strictly and numerical values within a range of process and measurement errors are allowed.

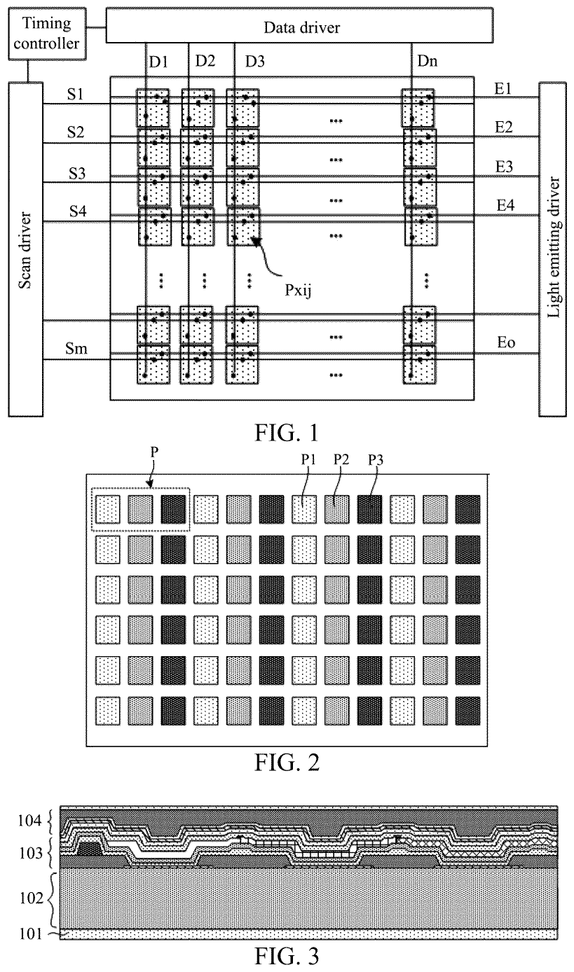

FIG. 1 is a schematic diagram of a structure of a display apparatus. As shown in FIG. 1, the display apparatus may include a timing controller, a data driver, a scan driver, a light emitting driver, and a pixel array. The timing controller is connected with the data driver, the scan driver, and the light emitting driver, respectively. The data driver is connected with a plurality of data signal lines (D1 to Dn), respectively. The scan driver is connected with a plurality of scan signal lines (S1 to Sm), respectively. The light emitting driver is connected with a plurality of light emitting signal lines (E1 to Eo), respectively. The pixel array may include a plurality of sub-pixels Pxij, i and j may be natural numbers, at least one sub-pixel Pxij may include a circuit unit and a light emitting unit, the circuit unit may include, at least, a pixel drive circuit connected to a scan signal line, a light emitting signal line and a data signal line, respectively. The light emitting unit may include a light emitting device connected to the pixel drive circuit of the circuit unit. In an exemplary implementation, the timing controller may provide a grayscale value and a control signal suitable for a specification of the data driver to the data driver, may provide a clock signal, a scan start signal and the like suitable for a specification of the scan driver to the scan driver, and may provide a clock signal, an emission stop signal and the like suitable for a specification of the light emitting driver to the light emitting driver. The data driver may generate data voltages to be provided to the data signal lines D1, D2, D3, . . . , and Dn using the gray-scale value and the control signal that are received from the timing controller. For example, the data driver may sample the gray-scale value using the clock signal and apply a data voltage corresponding to the gray-scale value to the data signal lines D1 to Dn by taking a pixel row as a unit, wherein n may be a natural number. The scan driver may generate a scan signal to be provided to the scan lines S1, S2, S3, . . . , and Sm by receiving the clock signal, the scan start signal and the like from the timing controller. For example, the scan driver may provide a scan signal with an on-level pulse to the scan signal lines S1 to Sm sequentially. For example, the scan driver may be constructed in a form of a shift register, and may generate a scan signal in a manner in which a scan start signal provided in a form of an on-level pulse is transmitted to a next-stage circuit sequentially under control of the clock signal, wherein m may be a natural number. The light emitting driver may receive a clock signal, an emission stop signal, etc., from the timing controller to generate an emission signal to be provided to the light emitting signal lines E1, E2, E3, . . . , and Eo. For example, the light emitting driver may sequentially provide an emission signal with an off-level pulse to the light emitting signal lines E1 to Eo. For example, the light emitting driver may be constructed in a form of a shift register, and may generate an emission signal in a manner of sequentially transmitting an emission stop signal provided in a form of an off-level pulse to a next-stage circuit under control of the clock signal, wherein o may be a natural number. In an exemplary embodiment, the pixel array may be disposed on the display substrate.

FIG. 2 is a schematic diagram of a planar structure of a display substrate. In an exemplary embodiment, the display substrate may include a display region 100 and a bezel region 200 located on a periphery of the display region 100. As shown in FIG. 2, the display region of the display substrate may include a plurality of pixel units P arranged in a matrix. At least one of the pixel units P may include a first sub-pixel P1 emitting light in a first color, a second sub-pixel P2 emitting light in a second color, and a third sub-pixel P3 emitting light in a third color. Each sub-pixel may include a circuit unit and a light emitting unit. The circuit unit may at least include a pixel drive circuit, the pixel drive circuit is connected with a scan signal line, a data signal line, and a light emitting signal line, respectively, and is configured to receive a data voltage transmitted by the data signal line and output a corresponding current to the light emitting device under control of the scan signal line and the light emitting signal line. The light emitting unit may at least include a light emitting device. The light emitting device is correspondingly connected with the pixel drive circuit of the sub-pixel where the light emitting device is located. The light emitting device is configured to emit light with a corresponding brightness in response to a current output by the pixel drive circuit of the sub-pixel where the light emitting device is located.

In an exemplary implementation, the first sub-pixel P1 may be a red (R) sub-pixel emitting red light, the second sub-pixel P2 may be a blue (B) sub-pixel emitting blue light, and the third sub-pixel P3 may be a green (G) sub-pixel emitting green light. In an exemplary implementation, a sub-pixel may be in a shape of a rectangle, a rhombus, a pentagon, or a hexagon. Three sub-pixels may be arranged in a manner of standing side by side horizontally, in a manner of standing side by side vertically, or in a delta-shaped arrangement, etc., which is not limited here in the present disclosure.

In an exemplary implementation, a pixel unit may include four sub-pixels, and the four sub-pixels may be arranged in a manner of standing side by side horizontally, in a manner of standing side by side vertically, or in a manner of a square, which is not limited here in the present disclosure.

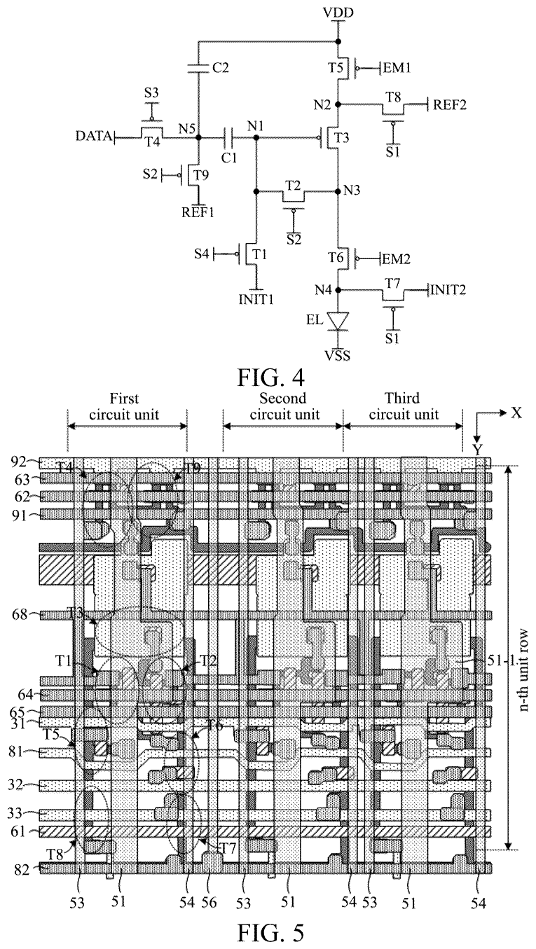

FIG. 3 illustrates schematically a sectional view of a structure of a display substrate, which illustrates a structure of three sub-pixels of the display substrate. As shown in FIG. 4, in a plane perpendicular to the display substrate, a display region of the display substrate may include a drive circuit layer 102 disposed on a substrate 101, a light emitting structure layer 103 disposed on a side of the drive circuit layer 102 away from the substrate 101, and an encapsulation structure layer 104 disposed on a side of the light emitting structure layer 103 away from the substrate 101. In some possible implementations, the display substrate may include another film layer, such as a touch structure layer, which is not limited here in the present disclosure.

In an exemplary implementation, the substrate 101 may be a flexible substrate, or may be a rigid substrate. The drive circuit layer 102 may include a plurality of circuit units, a circuit unit may at least include a pixel drive circuit, and the pixel drive circuit may include a plurality of transistors and a storage capacitor. The light emitting structure layer 103 may include a plurality of light emitting units, a light emitting unit may include, at least, a light emitting device, the light emitting device may include an anode, an organic light emitting layer, and a cathode. The anode is connected with a pixel drive circuit. The organic light emitting layer is connected with the anode. The cathode is connected with the organic light emitting layer. The organic light emitting layer emits light of a corresponding color under driving of the anode and the cathode. The encapsulation structure layer 104 may include a first encapsulation layer, a second encapsulation layer, and a third encapsulation layer that are stacked, wherein the first encapsulation layer and the third encapsulation layer may be made of an inorganic material, the second encapsulation layer may be made of an organic material, and the second encapsulation layer is disposed between the first encapsulation layer and the third encapsulation layer to form a laminated structure of inorganic material/organic material/inorganic material and ensure that external water vapor cannot enter the light emitting structure layer 103.

In an exemplary implementation, the organic light emitting layer may include an Emitting Layer (EML), and any one or more of following layers: a Hole Injection Layer (HIL), a Hole Transport Layer (HTL), an Electron Block Layer (EBL), a Hole Block Layer (HBL), an Electron Transport Layer (ETL), and an Electron Injection Layer (EIL).

A display substrate is provided in an exemplary embodiment of the present disclosure, which includes a plurality of circuit units, wherein at least one circuit unit includes a pixel drive circuit, the pixel drive circuit includes, at least, a first storage capacitor and a second storage capacitor, the first storage capacitor includes at least two first capacitor plates, orthographic projections of the two first capacitor plates on a substrate are overlapped, at least partially, with each other, the second storage capacitor includes at least two second capacitor plates, orthographic projections of the two second capacitor plates on the substrate are overlapped, at least partially, with each other; in a plane perpendicular to the display substrate, the display substrate includes a plurality of conductive layers, the first capacitor plate in the first storage capacitor and the second capacitor plate in the second storage capacitor are disposed in a same conductive layer, another first capacitor plate in the first storage capacitor and another second capacitor plate in the second storage capacitor are disposed in a same conductive layer, and one first capacitor plate in the first storage capacitor and one second capacitor plate in the second storage capacitor are connected with each other.

In an exemplary implementation, the plurality of conductive layers include, at least, a first conductive layer and a second conductive layer disposed sequentially on the substrate; the at least two first capacitor plates include a first plate disposed in the first conductive layer, and a third plate disposed in the second conductive layer, an orthographic projection of the first plate on the substrate is overlapped, at least partially, with an orthographic projection of the third plate on the substrate; the at least two second capacitor plates include a second plate disposed in the first conductive layer, a fourth plate disposed in the second conductive layer, an orthographic projection of the second plate on the substrate is overlapped, at least partially, with an orthographic projection of the fourth plate on the substrate, and the third plate is connected with the fourth plate.

In an exemplary implementation, the third plate of the first storage capacitor and the fourth plate of the second storage capacitor are connected with each other to form an integral structure.

In an exemplary implementation, the pixel drive circuit further includes a first initialization transistor, a compensation transistor, a data writing transistor, and a first reference transistor, which have a double gate structure, wherein a first electrode of the first initialization transistor is connected with a first initial signal line, a second electrode of the first initialization transistor is connected with a first electrode of the data writing transistor and the first plate, respectively, a first electrode of the data writing transistor is connected with the data signal line, a second electrode of the data writing transistor is connected with a second electrode of the first reference transistor, the third plate and the fourth plate, respectively, and a first electrode of the first reference transistor is connected with a first reference signal line.

In an exemplary implementation, at least one circuit unit further includes a first shield electrode whose orthographic projection on the substrate is overlapped, at least partially, with an orthographic projection of a node between two gate electrodes of the first initialization transistor on the substrate, and the orthographic projection of the first shield electrode on the substrate is overlapped, at least partially, with an orthographic projection of a node between two gate electrodes of the compensation transistor on the substrate.

In an exemplary implementation, the display substrate further includes at least one first power supply connection line extending along a first direction, and at least one first power line extending along a second direction, the first direction intersects with the second direction; the first power line and the first power supply connection line are disposed in different conductive layers, the first power line and the first power supply connection line are connected through a via to form a mesh structure for transmitting a first power supply signal, and the first shield electrode is connected with the first power supply connection line.

In an exemplary implementation, the first shield electrode includes a first extension section and a first shield section; a shape of the first extension section is a shape of strip extending along the second direction, and a shape of the first shield section is a shape of strip extending along the first direction; a first end of the first extension section is connected with the first power supply connection line, and a second end of the first extension section is connected with the first shield section; the first shield section includes a first shield end and a second shield end, an orthographic projection of the first shield end on the substrate is overlapped, at least partially, with the orthographic projection of the node between the two gate electrodes of the first initialization transistor in the circuit unit on the substrate, and an orthographic projection of the second shield end on the substrate is overlapped, at least partially, with an orthographic projection of a node between two gate electrodes of a compensation transistor in an adjacent circuit unit on the substrate.

In an exemplary implementation, the first shield electrode and the first power supply connection line are connected with each other to form an integral structure.

In an exemplary implementation, an orthographic projection of the first power supply connection line on the substrate is overlapped, at least partially, with the orthographic projection of the fourth plate on the substrate.

In an exemplary implementation, the display substrate further includes at least one second power supply connection line extending along a first direction, and at least one second power line extending along a second direction, the first direction intersects with the second direction; the second power line and the second power supply connection line are disposed in different conductive layers, the second power line and the second power supply connection line are connected through a via to form a mesh structure for transmitting a second power supply signal, and the first shield electrode is connected with the second power supply connection line.

In an exemplary implementation, the first shield electrode includes a first extension section and a first shield section; a shape of the first extension section is a shape of strip extending along the second direction, and a shape of the first shield section is a shape of strip extending along the first direction; a first end of the first extension section is connected with the second power supply connection line, and a second end of the first extension section is connected with the first shield section; the first shield section includes a first shield end and a second shield end, an orthographic projection of the first shield end on the substrate is overlapped, at least partially, with the orthographic projection of the node between the two gate electrodes of the first initialization transistor in the circuit unit on the substrate, and an orthographic projection of the second shield end on the substrate is overlapped, at least partially, with an orthographic projection of a node between two gate electrodes of a compensation transistor in an adjacent circuit unit on the substrate.

In an exemplary implementation, the first shield electrode and the second power supply connection line are connected with each other to form an integral structure.

In an exemplary implementation, an orthographic projection of the second power supply connection line on the substrate is overlapped, at least partially, with the orthographic projection of the third plate on the substrate.

In an exemplary implementation, at least one circuit unit further includes a second shield electrode, an orthographic projection of the second shield electrode on the substrate is overlapped, at least partially, with an orthographic projection of a node between two gate electrodes of the data writing transistor on the substrate.

In an exemplary implementation, at least one circuit unit further includes a third shield electrode, an orthographic projection of the third shield electrode on the substrate is overlapped, at least partially, with an orthographic projection of a node between two gate electrodes of the first reference transistor on the substrate.

In an exemplary implementation, the display substrate further includes at least one reference signal connection line extending along the first direction, and at least one reference signal line extending along the second direction, the first direction intersects with the second direction; the reference signal line and the reference signal connection line are disposed in different conductive layers, and the reference signal connection line are connected with the reference signal line through a via to form a mesh structure for transmitting a reference signal.

In an exemplary implementation, the display substrate further includes at least one initial signal line extending along the first direction and at least one initial connection line extending along the second direction, the first direction intersects with the second direction; the initial signal line and the initial connection line are disposed in different conductive layers, and the initial connection line is connected with the initial signal line through a via to form a mesh structure for transmitting an initial signal.

The display substrate of the present disclosure is illustrated with examples below through some exemplary embodiments.

FIG. 4 is an equivalent circuit diagram of a pixel drive circuit according to an exemplary embodiment of the present disclosure. In an exemplary implementation, the pixel drive circuit may have a structure of 3T1C, 4T1C, 5T1C, 5T2C, 6T1C, 7T1C, 8T1C or 9T2C. As shown in FIG. 4, the pixel drive circuit according to the exemplary embodiment of the present disclosure may have a 9T2C structure, and may include nine transistors (a first transistor T1 to a ninth transistor T9) and two storage capacitors (a first storage capacitor C1 and a second storage capacitor C2), and the pixel drive circuit is connected to 12 signal lines (a first scan signal line S1, a second scan signal line S2, a third scan signal line S3, a fourth scan signal line S4, a first light emitting signal line EM1, a second light emitting signal line EM2, a first initial signal line INIT1, a second initial signal line INIT2, a first reference signal line REF1, a second reference signal line REF2, a data signal line DATA and a first power line VDD), respectively.

In an exemplary implementation, the pixel drive circuit may include a first node N1, a second node N2, a third node N3, a fourth node N4, and a fifth node N5. The first node N1 is connected to a second electrode of the first transistor, a first electrode of the second transistor T2, a gate electrode of the third transistor T3 and a first terminal of the first storage capacitor C1, respectively. The second node N2 is connected to a first electrode of the third transistor T3, a second electrode of the eighth transistor T8, and a second electrode of the fifth transistor T5, respectively. The third node N3 is connected to a second electrode of the second transistor T2, a second electrode of the third transistor T3 and a first electrode of the sixth transistor T6, respectively. The fourth node N4 is connected to a second electrode of the sixth transistor T6 and a second electrode of the seventh transistor T7, respectively. The fifth node N5 is connected to a second electrode of the fourth transistor T4, a second electrode of the ninth transistor T9, a second terminal of the first storage capacitor C1 and a second terminal of the second storage capacitor C2, respectively.

In an exemplary implementation, the first terminal (lower plate) of the first storage capacitor C1 is connected to the first node N1, the second terminal (upper plate) of the first storage capacitor C1 is connected to the fifth node N5, a first terminal (upper plate) of the second storage capacitor C2 is connected to a first power line VDD, and the second terminal (lower plate) of the second storage capacitor C2 is connected to the fifth node N5.

In an exemplary implementation, a gate electrode of the first transistor T1 is connected to the fourth scan signal line S4, a first electrode of the first transistor T1 is connected to the first initial signal line INIT1, and the second electrode of the first transistor T1 is connected to the first node N1. When an ON level signal is applied to the fourth scan signal line S4, the first transistor T1 transmits a first initial voltage to the gate electrode of the third transistor T3 and the first terminal of the first storage capacitor C1, thereby releasing charges accumulated in the first storage capacitor C1 and achieving initialization.

In an exemplary implementation, a gate electrode of the second transistor T2 is connected to the second scan signal line S2, the first electrode of the second transistor T2 is connected to the first node N1, and the second electrode of the second transistor T2 is connected to the third node N3. When an ON level signal is applied to the second scan signal line S2, the second transistor T2 enables the gate electrode of the third transistor T3 to be connected with the second electrode of the third transistor T3.

In an exemplary implementation, the gate electrode of the third transistor T3 is connected to the first node N1. That is, the gate electrode of the third transistor T3 is connected to the first terminal of the first storage capacitor C1, the first electrode of the third transistor T3 is connected to the second node N2, and the second electrode of the third transistor T3 is connected to the third node N3. The third transistor T3 may be referred to as a drive transistor, and the third transistor T3 determines a magnitude of the drive current according to a potential difference between the gate electrode and the first electrode of the third transistor T3.

In an exemplary implementation, a gate electrode of the fourth transistor T4 is connected to the third scan signal line S3, a first electrode of the fourth transistor T4 is connected to the data signal line Data, and the second electrode of the fourth transistor T4 is connected with the fifth node N5. When an ON level signal is applied to the third scan signal line S3, the fourth transistor T4 enables a data voltage of the data signal line DATA to be input to the second terminal of the first storage capacitor C1 and the second terminal of the second storage capacitor C2.

In an exemplary implementation, a gate electrode of the fifth transistor T5 is connected to the first light emitting signal line EM1, a first electrode of the fifth transistor T5 is connected to the first power line VDD, and the second electrode of the fifth transistor T5 is connected to the second node N2. A gate electrode of the sixth transistor T6 is connected to the second light emitting signal line EM2, the first electrode of the sixth transistor T6 is connected to the third node N3, and the second electrode of the sixth transistor T6 is connected to the fourth node N4. When an ON level signal is applied to the first light emitting signal line EM1 and the second light emitting signal line EM2, the fifth transistor T5 and the sixth transistor T6 form a drive current path between the first power line VDD and the second power line VSS to enable a light emitting device EL to emit light.

In an exemplary implementation, a gate electrode of the seventh transistor T7 is connected to the first scan signal line S1, a first electrode of the seventh transistor T7 is connected to the second initial signal line INIT2, and a second electrode of the seventh transistor T7 is connected to the fourth node N4. When the ON level signal is applied to the first scan signal line S1, the seventh transistor T7 transmits a second initial voltage to a first electrode of the light emitting device EL, so that accumulated charges in the first electrode of the light emitting device EL are released, and initialization is achieved.

In an exemplary implementation, a gate electrode of the eighth transistor T8 is connected to the first scan signal line S1, a first electrode of the eighth transistor T8 is connected to the second reference signal line REF2, and the second electrode of the eighth transistor T8 is connected to the second node N2. When the ON level signal is applied to the first scan signal line S1, the eighth transistor T8 transmits a second reference signal to the second node N2.

In an exemplary implementation, a gate electrode of the ninth transistor T9 is connected to the second scan signal line S2, a first electrode of the ninth transistor T9 is connected to the first reference signal line REF1, and a second electrode of the ninth transistor T9 is connected to the fifth node N5. When the ON level signal is applied to the second scan signal line S2, the ninth transistor T9 transmits the first reference signal to the fifth node N5.

In an exemplary implementation, the light emitting device EL may be an OLED including a first electrode (anode), an organic light emitting layer, and a second electrode (cathode), which are stacked, or may be a QLED including a first electrode (anode), a quantum dot light emitting layer, and a second electrode (cathode), which are stacked. The first electrode of the light emitting device EL is connected to the fourth node N4, the second electrode of the light emitting device EL is connected to the second power line VSS, a signal in the second power line VSS is a continuously supplied low-level signal, and a signal in the first power line VDD is a continuously supplied high-level signal.

In an exemplary implementation, the first transistor T1 to the ninth transistor T9 may be P-type transistors, or may be N-type transistors. Usage of transistors with a same type in the pixel drive circuit may simplify a process flow, reduce a process difficulty of a display panel, and improve a yield of a product. In some possible implementations, the first transistor T1 to the ninth transistor T9 may include a P-type transistor and an N-type transistor.

In an exemplary implementation, for all of the first transistor T1 to the ninth transistor T9, low temperature poly silicon film transistors may be used, oxide film transistors may be used, or both of low temperature poly silicon film transistors and oxide film transistors may be used. An active layer of a low temperature poly silicon thin film transistor may be made of Low Temperature Poly silicon (LTPS for short), and an active layer of an oxide thin film transistor may be made of an oxide semiconductor (Oxide). The low temperature poly silicon thin film transistor has advantages, such as a high mobility and fast charging, and the oxide thin film transistor has advantages, such a low drain current. The low temperature poly silicon thin film transistor and the oxide thin film transistor are integrated on one display substrate, that is a LTPS+Oxide (LTPO for short) display substrate, so that advantages of the low temperature poly silicon thin film transistor and the oxide thin film transistor may be utilized, low-frequency drive may be achieved, power consumption may be reduced, and display quality may be improved.

In an exemplary implementation, an operation process of the pixel drive circuit shown in FIG. 4 may include a first stage to a fifth stage.

In the first stage, which may include a plurality of sub-stages that are repeatedly executed, each sub-stage may include a first sub-stage and a second sub-stage that are sequentially executed.

In the first sub-stage, a signal in the fourth scan signal line S4 and a signal in the first light emitting signal line EM1 are ON level signals, and signals in other signal lines are OFF level signals. The signal in the fourth scan signal line S4 being an ON level enables the first transistor T1 to be turned on, and a first initial signal in the first initial signal line INIT1 can be supplied to the first node N1 to initialize the first node N1. When the third transistor T3 is a P-type transistor, the third transistor T3 is turned on. The ON level signal in the first light emitting signal line EM1 may enable the fifth transistor T5 to be turned on, and a first power supply signal in the first power line VDD may be supplied to the second node N2.

In the second sub-stage, a signal in the second scan signal line S2 and the signal in the first light emitting signal line EM1 are ON level signals, and signals in the other signal lines are OFF level signals. The signal in the second scan signal line S2 is an ON level signal, which may enable the second transistor T2 to be turned on to connect the first node N1 to the third node N3, and a threshold voltage of the third transistor T3 is written to the first node N1. The signal in the second scan signal line S2 is the ON level signal, which may enable the ninth transistor T9 to be turned on, so that the first reference signal of the first reference signal line REF1 is supplied to the fifth node N5 to initialize the fifth node N5. The ON level signal in the first light emitting signal line EM1 may enable the fifth transistor T5 to be turned on, and the first power supply signal in the first power line VDD may be supplied to the second node N2.

In the second stage, a signal in the third scan signal line S3 is an ON level signal, and signals in the other signal lines are OFF level signals. The signal in the third scan signal line S3 is an ON level signal, which may enable the fourth transistor T4 to be turned on, and the data voltage supplied by the data signal line DATA is written to the fifth node N5.

In the third stage, a signal in the first scan signal line S1 is an ON level signal, and signals in the other signal lines are OFF level signals. The signal of the first scan signal line S1 is an ON level signal, which may enable the seventh transistor T7 to be turned on, and the second initial signal of the second initial signal line INIT2 can be written to the fourth node N4 to initialize the fourth node N4, so as to avoid a residual signal in a previous frame affecting display in the present frame. The signal in the first scan signal line S1 is an ON level signal, which enables the eighth transistor T8 to be turned on, and the second reference signal in the second reference signal line REF2 can be written to the second node N2.

In the fourth stage, the signal in the second light emitting signal line EM2 is an ON level signal, and signals in the other signal lines are OFF level signals. The signal of the second light emitting signal line EM2 is an ON level signal, which enables the sixth transistor T6 to be turned on to connect the third node N3 with the fourth node N4, so that the third node N3 and the fourth node N4 are at a same potential.

In the fifth stage, the signals in the first and second light emitting signal lines EM1 and EM2 are ON level signals, and signals in the other signal lines are OFF level signals. The signals in the first and second light emitting signal lines EM1 and EM2 are ON level signals, which enables the fifth transistor T5 and the sixth transistor T6 to be turned on, and the first power supply signal in the first power line VDD can supply a driving signal to the light emitting device EL through the turned-on fifth transistor T5, the third transistor T3 and the sixth transistor T6 to drive the light emitting device EL to emit light.

In an exemplary implementation, because the drive transistor (i.e., the third transistor T3) is in a same state for a long time, electrons are trapped in traps, resulting in hysteresis. Therefore, in the first stage, not only the hysteresis of the drive transistor can be reduced, but also potential stability at the first node N1 can be ensured, by performing initialization and threshold voltage writing for the first node N1 several times (e.g., three times). In the third stage S3, the second reference signal is written to the second node N2, which is beneficial to reducing the hysteresis of the drive transistor by changing a potential at the second node N2. In the fourth stage S4, by connecting the third node N3 with the fourth node N4, the potential at the fourth node N4 can be increased, which is beneficial to reducing time required to reach an onset voltage of the light emitting device later.

The pixel drive circuit according to the present disclosure can effectively improve the hysteresis condition of the drive transistor, which is beneficial to improving display effect.

FIG. 5 is a schematic diagram of a planar structure of a display substrate in an exemplary embodiment of the present disclosure, illustrating a structure of a pixel drive circuit in three circuit units (a first circuit unit, a second circuit unit, and a third circuit unit) in the display substrate. In an exemplary embodiment, the display substrate may include a drive circuit layer disposed on a substrate, and a light emitting structure layer disposed on a side of the drive circuit layer away from the substrate. The drive circuit layer may include, at least, a plurality of circuit units, the light emitting structure layer may include, at least, a plurality of light emitting units, at least one circuit unit includes a pixel drive circuit, the at least one light emitting unit includes a light emitting device which may include, at least, an anode, an organic light emitting layer, and a cathode, wherein the anode in the light emitting unit is connected to the pixel drive circuit in a corresponding circuit unit.

In an exemplary implementation, the circuit units mentioned in the present disclosure refer to regions divided according to pixel drive circuits, and the light emitting units mentioned in the present disclosure refer to regions divided according to light emitting devices. In an exemplary embodiment, a position of an orthographic projection of a light emitting unit on the substrate may correspond to a position of an orthographic projection of a circuit unit on the substrate, or the position of the orthographic projection of the light emitting unit on the substrate may not correspond to the position of the orthographic projection of the circuit unit on the substrate.

In an exemplary embodiment, a plurality of circuit units sequentially disposed along a first direction X are referred to as a unit row, and a plurality of circuit units sequentially disposed along a second direction Y are referred to as a unit column. A plurality of unit rows and a plurality of unit columns form an array of circuit units arranged in an array, and the first direction X intersects with the second direction Y.

As shown in FIG. 5, in an exemplary embodiment, at least one pixel drive circuit may include a first transistor T1 as a first initialization transistor, a second transistor T2 as a compensation transistor, a third transistor T3 as a drive transistor, a fourth transistor T4 as a data writing transistor, a fifth transistor T5 as a first light emitting transistor, a sixth transistor T6 as a second light emitting transistor, a seventh transistor T7 as a second initialization transistor, an eighth transistor T8 as a second reference transistor, a ninth transistor T9 as a first reference transistor, a first storage capacitor and a second storage capacitor.

In an exemplary implementation, a gate electrode of the first transistor T1 is connected with a fourth scan signal line 64, a first electrode of the first transistor T1 is connected with a first initial signal line 81, and a second electrode of the first transistor T1 is connected with a first electrode of the second transistor T2, and a first plate 71 of the first storage capacitor, respectively. A gate electrode of the second transistor T2 is connected with a fifth scan signal line 65, and a second electrode of the second transistor T2 is connected with a second electrode of the third transistor T3, and a first electrode of the sixth transistor T6, respectively. A gate electrode of the third transistor T3 serves as the first plate 71 of the first storage capacitor, and a first electrode of the third transistor T3 is connected with a second electrode of the fifth transistor T5, and a second electrode of the eighth transistor T8, respectively. A gate electrode of the fourth transistor T4 is connected with the third scan signal line 63, a first electrode of the fourth transistor T4 is connected with a data signal line 53, and a second electrode of the fourth transistor T4 is connected with a second electrode of the ninth transistor T9, a third plate 73 of the first storage capacitor, and a fourth plate 74 of the second storage capacitor, respectively. A gate electrode of the fifth transistor T5 is connected with a first light emitting signal line 31, and a first electrode of the fifth transistor T5 is connected with a first power line 51. A gate electrode of the sixth transistor T6 is connected with a second light emitting signal line 32, and a second electrode of the sixth transistor T6 is connected with a second electrode of the seventh transistor T7. A gate electrode of the seventh transistor T7 is connected with the first scan signal line 61, and a first electrode of the seventh transistor T7 is connected with a second initial signal line 82. A gate electrode of the eighth transistor T8 is connected with the first scan signal line 61, and a first electrode of the eighth transistor T8 is connected with a second reference signal line 92. A gate electrode of the ninth transistor T9 is connected with a second scan signal line 62, and a first electrode of the ninth transistor T9 is connected to the first reference signal line 91.

In an exemplary implementation, the second scan signal line 62 and the fifth scan signal line 65 transmit a same scan signal.

In an exemplary implementation, shapes of the first scan signal line 61, the second scan signal line 62, the third scan signal line 63, the fourth scan signal line 64, the fifth scan signal line 65, the first light emitting signal line 31, the second light emitting signal line 32, the first initial signal line 81, the second initial signal line 82, the first reference signal line 91, and the second reference signal line 92 may be line shapes in which a main portion extends along the first direction X, and shapes of the first power line 51 and the data signal line 53 may be line shapes in which a main portion extends along a second direction Y.

In an exemplary implementation, the display substrate may further include a repair line 33 whose shape may be a line shape in which a main portion extends along the first direction X.

In an exemplary implementation, the display substrate may further include at least one first power line 51 extending along the second direction Y, and at least one first power supply connection line 68 extending along the first direction X. In an exemplary implementation, the first power line 51 is connected to pixel drive circuits in the plurality of circuit units, and is configured to continuously supply a high-level signal to the pixel drive circuits. In an exemplary implementation, the first power line 51 extending along the second direction Y and the first power supply connection line 68 extending along the first direction X are connected with each other to form a mesh structure for transmitting a first power supply signal.

In the present disclosure, A extends along a B direction means that A may include a main portion and a secondary portion connected with the main portion, the main portion is a line, a line section, or a strip-shaped body, the main portion extends along the B direction, and a length of the main portion extends along the B direction is greater than a length of the secondary portion extends along another direction.

In an exemplary implementation, in a plane perpendicular to the display substrate, a drive circuit layer may include a semiconductor layer, a first conductive layer, a second conductive layer, a third conductive layer, and a fourth conductive layer that are sequentially provided on the substrate. In an exemplary implementation, the first power line 51 and the first power supply connection line 68 are disposed in different conductive layers, and the first power line 51 and the first power supply connection line 68 are connected through a via.

In an exemplary implementation, the first power supply connection line 68 may be disposed in the third conductive layer, and the first power line 51 may be disposed in the fourth conductive layer.

In an exemplary implementation, the display substrate may further include at least one second initial signal line 82 extending along the first direction X, and at least one initial connection line 56 extending along the second direction Y. The second initial signal line 82 is configured to provide a second initial signal to the pixel drive circuit. The initial connection line 56 extending along the second direction Y and the second initial signal line 82 extending along the first direction X are connected with each other to form a mesh structure for transmitting the second initial signal.

In an exemplary implementation, the second initial signal line 82 and the initial connection line 56 may be disposed in different conductive layers, and the initial connection line 56 is connected with the second initial signal line 82 through a via.

In an exemplary implementation, the second initial signal line 82 may be disposed in the third conductive layer, and the initial connection line 56 may be disposed in the fourth conductive layer.

In an exemplary implementation, the display substrate further includes at least one first reference signal line 91 extending along the first direction X, and at least one reference signal connection line 54 extending along the second direction Y. The first reference signal line 91 is configured to provide a reference signal to the pixel drive circuit. In an exemplary implementation, the reference signal connection line 54 extending along the second direction Y and the first reference signal line 91 extending along the first direction X are connected with each other, forming a mesh structure for transmitting the first reference signal.

In an exemplary implementation, the first reference signal line 91 and the reference signal connection line 54 are disposed in different conductive layers, and the reference signal connection line 54 is connected with the first reference signal line 91 through a via.

In an exemplary implementation, the first reference signal line 91 may be disposed in the third conductive layer, and the reference signal connection line 54 may be disposed in the fourth conductive layer.

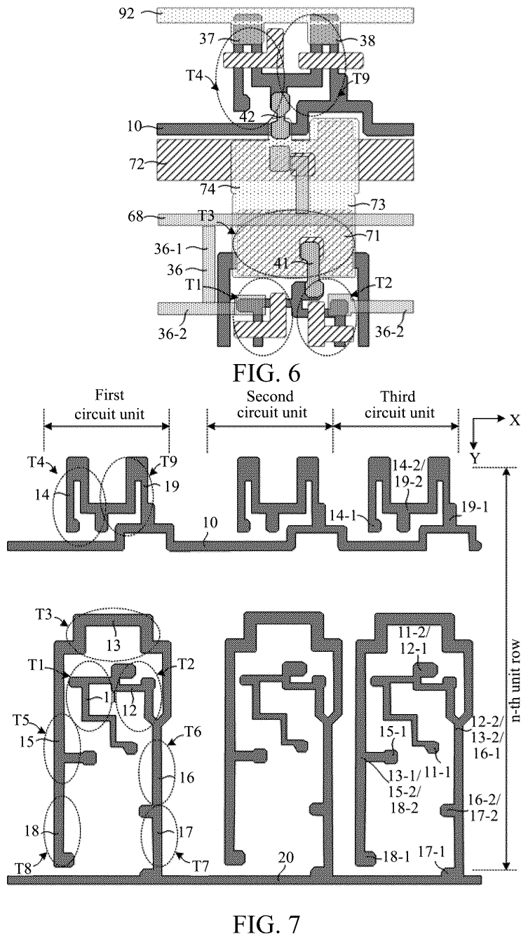

FIG. 6 is a schematic diagram of a regional structure of the first storage capacitor and the second storage capacitor in FIG. 5. As shown in FIGS. 5 and 6, in an exemplary implementation, at least two first capacitor plates of the first storage capacitor may be a first plate 71 and a third plate 73, an orthographic projection of the first plate 71 on the substrate is overlapped, at least partially, with an orthographic projection of the third plate 73 on the substrate. At least two second capacitor plates of the second storage capacitor may be a second plate 72 and a fourth plate 74, wherein an orthographic projection of the second plate 72 on the substrate is overlapped, at least partially, with an orthographic projection of the fourth plate 74 on the substrate, and the third plate 73 is connected with the fourth plate 74.

In an exemplary implementation, the first and second plates 71 and 72 may be disposed in the first conductive layer, and the third and fourth plates 73 and 74 may be disposed in the second conductive layer.

In an exemplary implementation, the third plate 73 of the first storage capacitor and the fourth plate 74 of the second storage capacitor may be connected with each other to form an integral structure.

As shown in FIGS. 5 and 6, in an exemplary implementation, at least one circuit unit may further include a first connection electrode 41 connected to the second electrode of the first transistor T1, the first electrode of the second transistor T2, and the first plate 71 of the first storage capacitor, respectively, and the first connection electrode 41 may serve as a first node of the pixel drive circuit.

In an exemplary implementation, at least one circuit unit may further include a power supply shield block 51-1 connected with the first power line 51, an orthographic projection of the power supply shield block 51-1 on the substrate is overlapped, at least partially, with an orthographic projection of the first connection electrode 41 on the substrate, so as to shield an influence of other signals in the pixel drive circuit on the first node.

In an exemplary implementation, at least one circuit unit may further include a second connection electrode 42 connected with the second electrode of the fourth transistor T4, the second electrode of the ninth transistor T9, the third plate 73 of the first storage capacitor and the fourth plate 74 of the second storage capacitor, respectively, and the second connection electrode 42 may serve as a fifth node N5 in the pixel drive circuit.

In an exemplary implementation, an orthographic projection of the first power line 51 on the substrate is overlapped, at least partially, with an orthographic projection of the second connection electrode 42 on the substrate, so as to shield an influence of other signals in the pixel drive circuit on the fifth node.

In an exemplary implementation, at least one circuit unit further includes a first shield electrode 36 whose orthographic projection on the substrate is overlapped, at least partially, with an orthographic projection of a node between two gate electrodes of the first transistor T1 on the substrate, and the orthographic projection of the first shield electrode 36 on the substrate is overlapped, at least partially, with an orthographic projection of a node between two gate electrodes of the second transistor T2 on the substrate. In an exemplary implementation, the first shield electrode 36 is configured to shield an influence of data voltage jump on the first transistor T1 and the second transistor T2, to avoid the data voltage jump affecting normal operation of the pixel drive circuit, and to improve the display effect.

In an exemplary implementation, the first shield electrode 36 is connected to the first power supply connection line 68.

In an exemplary implementation, the first shield electrode 36 includes a first extension section 36-1 and a first shield section 36-2, wherein the first extension section 36-1 is in a shape of strip extending along the second direction Y, and the first shield section 36-2 is in a shape of strip extending along the first direction X, a first end of the first extension section 36-1 is connected with the first power supply connection line 68, and a second end of the first extension section 36-1 is connected with the first shield section 36-2. The first shield section 36-2 includes a first shield end and a second shield end, an orthographic projection of the first shield end on the substrate is overlapped, at least partially, with an orthographic projection of a node between two gate electrodes of a first transistor T1 in a circuit unit on the substrate, and an orthographic projection of the second shield end on the substrate is overlapped, at least partially, with an orthographic projection of a node between two gate electrodes of a second transistor T2 in the adjacent circuit unit on the substrate.

In an exemplary implementation, the first shield electrode 36 and the first power supply connection line 68 are connected with each other to form an integral structure.

In an exemplary implementation, at least one circuit unit further includes a second shield electrode 37 connected to the second reference signal line 92, wherein an orthographic projection of the second shield electrode 37 on the substrate is overlapped, at least partially, with an orthographic projection of a node between two gate electrodes of the fourth transistor T4 on the substrate. In an exemplary implementation, the second shield electrode 37 is configured to shield an influence of data voltage jump on the fourth transistor T4, to avoid the data voltage jump affecting normal operation of the pixel drive circuit, and to improve the display effect.

In an exemplary implementation, the second shield electrode 37 and the second reference signal line 92 are connected with each other to form an integral structure.

In an exemplary implementation, at least one circuit unit further includes a third shield electrode 38 connected to the second reference signal line 92, wherein an orthographic projection of the third shield electrode 38 on the substrate is overlapped, at least partially, with an orthographic projection of a node between two gate electrodes of the ninth transistor T9 on the substrate. In an exemplary implementation, the third shield electrode 38 is configured to shield an influence of data voltage jump on the ninth transistor T9, to avoid the data voltage jump affecting normal operation of the pixel drive circuit, and to improve the display effect.

In an exemplary implementation, the third shield electrode 38 and the second reference signal line 92 are connected with each other to form an integral structure.

Exemplary description is made below through a manufacturing process of a display substrate. A “patterning process” mentioned in the present disclosure includes photoresist coating, mask exposure, development, etching, photoresist stripping, etc., for a metal material, an inorganic material, or a transparent conductive material, and includes organic material coating, mask exposure, development, etc., for an organic material. Deposition may be any one or more of sputtering, evaporation, and chemical vapor deposition, coating may be any one or more of spray coating, spin coating, and inkjet printing, and etching may be any one or more of dry etching and wet etching, the present disclosure is not limited thereto. A “thin film” refers to a layer of thin film made of a certain material on a substrate using deposition, coating, or other processes. If the “thin film” does not need to be processed through a patterning process in the entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process. “A and B are disposed in a same layer” in the present disclosure means that A and B are formed simultaneously through a same patterning process, and a “thickness” of a film layer is a dimension of the film layer in a direction perpendicular to a display substrate. In an exemplary implementation of the present disclosure, “an orthographic projection of B being within a range of an orthographic projection of A” or “an orthographic projection of A containing an orthographic projection of B” means that a boundary of the orthographic projection of B falls within a range of a boundary of the orthographic projection of A, or the boundary of the orthographic projection of A is overlapped with the boundary of the orthographic projection of B.

In an exemplary implementation, three circuit units (a first circuit unit, a second circuit unit, and a third circuit unit) in an n-th unit row are taken as an example, the manufacturing process of a display substrate in the embodiment may include the following acts.
(11) A pattern of a semiconductor layer is formed. In an exemplary implementation, forming the pattern of the semiconductor layer may include: a first insulating thin film and a semiconductor thin film are sequentially deposited on a substrate, and the semiconductor thin film is patterned through a patterning process to form a first insulation layer that covers the substrate and the semiconductor layer disposed on the first insulation layer, as shown in FIG. 7.

In an exemplary implementation, a semiconductor layer of each circuit unit in the display substrate may include, at least, a first active layer 11 of a first transistor T1, a second active layer 12 of a second transistor T2, a third active layer 13 of a third transistor T3, a fourth active layer 14 of a fourth transistor T4, a fifth active layer 15 of a fifth transistor T5, a sixth active layer 16 of a sixth transistor T6, a seventh active layer 17 of a seventh transistor T7, an eighth active layer 18 of an eighth transistor T8 and a ninth active layer 19 of a ninth transistor T9, and the first to third active layers 11 to 13 and the fifth to eighth active layers 15 to 18 may be connected with each other to form an integral structure, and the fourth and ninth active layers 14 and 19 may be connected with each other to form an integral structure.

In an exemplary implementation, a fourth active layer 14 and a ninth active layer 19 in an n-th unit row may be located on a side of the third active layer 13 close to an (n−1)-th unit row. That is, the fourth active layer 14 and the ninth active layer 19 may be located on a side of the third active layer 13 of the circuit unit in a direction opposite to the second direction Y. The first active layer 11, the second active layer 12, the fifth to eighth active layers 15 to 18 in the n-th unit row may be located on a side of the third active layer 13 close to an (n+1)-th unit row. That is, the first active layer 11, the second active layer 12, the fifth to eighth active layer 15 to 18 may be located on a side of the third active layer 13 of the circuit unit in the second direction Y.

In an exemplary implementation, the first active layer 11 may be located on a side of the third active layer 13 of the circuit unit in the second direction Y, the fifth active layer 15 may be located on a side of the first active layer 11 of the circuit unit in the second direction Y, and the eighth active layer 18 may be located on a side of the fifth active layer 15 of the circuit unit in the second direction Y. The second active layer 12 may be located on a side of the third active layer 13 of the circuit unit in the second direction Y, the sixth active layer 16 may be located on a side of the second active layer 12 of the circuit unit in the second direction Y, and the seventh active layer 17 may be located on a side of the sixth active layer 16 of the circuit unit in the second direction Y.

In an exemplary implementation, the fifth active layer 15 and the eighth active layer 18 may be located on a side of the third active layer 13 of the circuit unit in a first direction X (e.g. a side in a direction opposite to the first direction X), and the sixth active layer 16 and the seventh active layer 17 may be located on the other side of the third active layer 13 of the circuit unit in the first direction X (e.g. a side in the first direction X).

In an exemplary implementation, shapes of the first and second active layers 11 and 12 may be “L” shaped, a shape of the third active layer 13 may be “C” shaped, shapes of the fourth and ninth active layers 14 and 19 may be “n” shaped, and shapes of the fifth, sixth, seventh and eighth active layers 15, 16, 17 and 18 may be “I” shaped.

In an exemplary implementation, an active layer of each transistor may include a first region, a second region, and a channel region located between the first region and the second region. In an exemplary implementation, a second region 11-2 of the first active layer and a first region 12-1 of the second active layer may be connected with each other, the second region 11-2 of the first active layer may serve as the first region 12-1 of the second active layer. A first region 13-1 of the third active layer, a second region 15-2 of the fifth active layer, and a second region 18-2 of the eighth active layer may be connected with each other, the first region 13-1 of the third active layer may serve as the second region 15-2 of the fifth active layer and the second region 18-2 of the eighth active layer at the same time, forming a second node N2 of the pixel drive circuit. A second region 12-2 of the second active layer, a second region 13-2 of the third active layer and a first region 16-1 of the sixth active layer may be connected with each other, the second region 13-2 of the third active layer may serve as the second region 12-2 of the second active layer and the first region 16-1 of the sixth active layer at the same time, forming a third node N3 of the pixel drive circuit. A second region 14-2 of the fourth active layer and a second region 19-2 of the ninth active layer may be connected with each other, the second region 14-2 of the fourth active layer may serve as the second region 19-2 of the ninth active layer. A second region 16-2 of the sixth active layer and a second region 17-2 of the seventh active layer may be connected with each other. A second region 16-2 of the sixth active layer may serve as a second region 17-2 of the seventh active layer, forming a fourth node N4 of the pixel drive circuit. A first region 11-1 of the first active layer, a first region 14-1 of the fourth active layer, a first region 15-1 of the fifth active layer, a first region 17-1 of the seventh active layer, a first region 18-1 of the eighth active layer and a first region 19-1 of the ninth active layer may be individually provided.

In an exemplary implementation, the display substrate may further include a first active connection line 10 and a second active connection line 20. The first active connection line 10 may be located on a side of the ninth active layer 19 in the second direction Y, and connected to a first region 19-1 of a ninth active layer of each circuit unit. The second active connection line 20 may be located on a side of the seventh active layer 17 in the second direction Y, and connected to a first region 17-1 of a seventh active layer of each circuit unit.

In an exemplary implementation, a shape of the first active connection line 10 may be in a shape of bend line in which a main portion extends along the first direction X, and the first active connection line 10 and ninth active layers of a plurality of circuit units may be connected with each other to form an integral structure. Because the first regions of the ninth active layers are connected with the first reference signal line formed subsequently, the first active connection line 10 may be reused as the first reference signal line extending along the first direction X, which can not only ensure that first regions of ninth active layers in the unit row are at a same potential, but also reduce a voltage drop of a first reference signal, which is beneficial to improving uniformity of a panel, avoiding display defect of the display substrate, and ensuring the display effect of the display substrate.

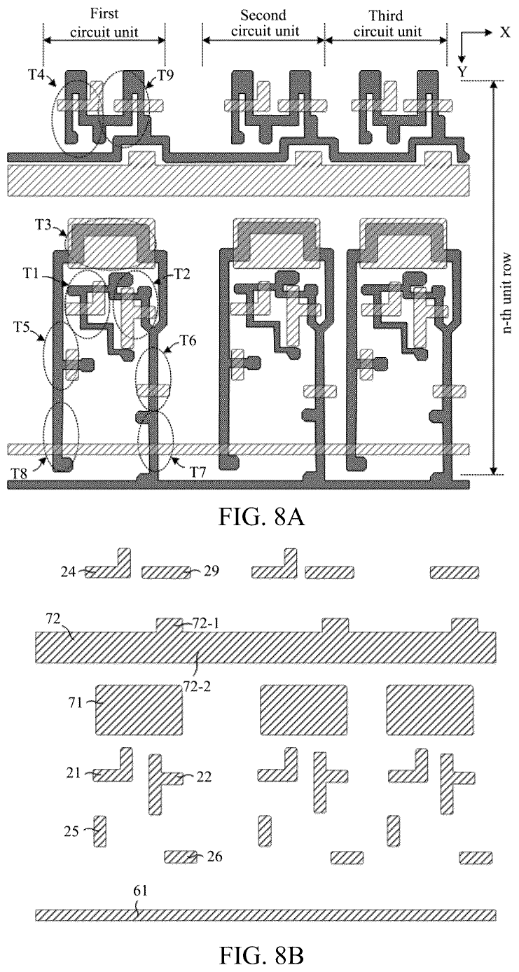

In an exemplary implementation, a shape of the second active connection line 20 may be in a shape of straight line in which a main portion extends along the first direction X, and the second active connection line 20 and seventh active layers of a plurality of circuit units may be connected with each other to form an integral structure. Because the first regions of the seventh active layers are connected with a second initial signal line formed subsequently, the second active connection line 20 may be reused as the second initial signal line extending along the first direction X, which can not only ensure that first regions of the plurality of seventh active layers in the unit row are at a same potential, but also reduce a voltage drop of a second initial signal, which is beneficial to improving the uniformity of the panel, avoiding the display defect of the display substrate, and ensuring the display effect of the display substrate.
(12) A pattern of a first conductive layer is formed. In an exemplary implementation, forming the pattern of the first conductive layer may include: a second insulating thin film and a first conductive thin film are sequentially deposited on the substrate on which the aforementioned patterns are formed, and the first conductive thin film is patterned through a patterning process to form a second insulation layer that covers the pattern of the semiconductor layer and the pattern of the first conductive layer disposed on the second insulation layer, as shown in FIGS. 8A and 8B, and FIG. 8B is a schematic diagram of the first conductive layer in FIG. 8A. In an exemplary implementation, the first conductive layer may be referred to as a first gate metal (GATE1) layer.

In an exemplary implementation, a pattern of a first conductive layer of each circuit unit in the display substrate includes, at least, a first gate electrode 21, a second gate electrode 22, a fourth gate electrode 24, a fifth gate electrode 25, a sixth gate electrode 26, a ninth gate electrode 29, a first scan signal line 61, a first plate 71 of a first storage capacitor, and a second plate 72 of a second storage capacitor.

In an exemplary implementation, a shape of the first gate electrode 21 may be “L” shaped, the first gate electrode 21 may be located at a side of the first plate 71 in the second direction Y, and a region where the first gate electrode 21 is overlapped with the first active layer may serve as a gate electrode of the first transistor T1 having a double gate structure.

In an exemplary implementation, a shape of the second gate electrode 22 may be “T” shaped, the second gate electrode 22 may be located at the side of the first plate 71 in the second direction Y, and a region where the second gate electrode 22 is overlapped with the second active layer may serve as a gate electrode of the second transistor T2 with a double gate structure.

In an exemplary implementation, a shape of the fourth gate electrode 24 may be “L” shaped, the fourth gate electrode 24 may be located on a side of the second plate 72 in a direction opposite to the second direction Y, and a region where the fourth gate electrode 24 is overlapped with the fourth active layer may serve as a gate electrode of the fourth transistor T4 with a double-gate structure.

In an exemplary embodiment, a shape of the fifth gate electrode 25 may be a shape of strip extending along the second direction Y, the fifth gate electrode 25 may be located on a side of the first gate electrode 21 in the second direction Y, and a region where the fifth gate electrode 25 is overlapped with the fifth active layer may serve as a gate electrode of the fifth transistor T5.

In an exemplary implementation, a shape of the sixth gate electrode 26 may be a shape of strip extending along the first direction X, the sixth gate electrode 26 may be located on a side of the second gate electrode 22 in the second direction Y, and a region where the sixth gate electrode 26 is overlapped with the sixth active layer may serve as a gate electrode of the sixth transistor T6.

In the exemplary embodiment, a shape of the ninth gate electrode 29 may be a shape of strip extending along the first direction X, the ninth gate electrode 29 may be located on a side of the second plate 72 in a direction opposite to the second direction Y, and a region where the ninth gate electrode 29 is overlapped with the ninth active layer may serve as a gate electrode of the ninth transistor T9 with a double gate structure.

In an exemplary embodiment, a shape of the first scan signal line 61 may be a shape of line in which a main portion extends along the first direction X, the first scan signal line 61 may be located on a side of the fifth gate electrode 25 and the sixth gate electrode 26 in the second direction Y, a region where the first scan signal line 61 is overlapped with the seventh active layer may serve as a gate electrode of the seventh transistor T7, and a region where the first scan signal line 61 is overlapped with the eighth active layer may serve as a gate electrode of the eighth transistor T8.

In an exemplary implementation, a shape of the first plate 71 of the first storage capacitor may be a shape of rectangle in which corners of the rectangle may be chamfered, an orthographic projection of the first plate 71 on the substrate is overlapped, at least partially, with an orthographic projection of the third active layer of the third transistor T3 on the substrate, and the first plate 71 may serve as a lower plate of the first storage capacitor and a gate electrode of the third transistor T3 at the same time.

In an exemplary implementation, a shape of the second plate 72 of the second storage capacitor may be a shape of rectangle, in which corners of the rectangle may be chamfered, and the second plate 72 may be located at a side opposite to the first plate 71 in the second direction Y, and at a side of the fourth gate electrode 24 and the ninth gate electrode 29 in the second direction Y. That is, in the second direction Y, the second plate 72 is located between the first plate 71 and the fourth gate electrode 24 (the ninth gate electrode 29), and an orthographic projection of the second plate 72 on the substrate is not overlapped with an orthographic projection of the semiconductor layer on the substrate. In an exemplary implementation, the third plate 72 may serve as a lower plate of the second storage capacitor.

In an exemplary implementation, a region where the first active connection line 10 is connected to the first region of the ninth active layer is bent towards the ninth active layer, so that a recess is formed on a side of the first active connection line 10 away from the ninth active layer. At a side of the second plate 72 close to the first active connection line 10, a protrusion 72-1 in a rectangular shape is provided, a first end of the protrusion 72-1 is connected with the second plate 72, and a second end of the protrusion 72-1 extends into the recess of the first active connection line 10.

In an exemplary implementation, the second plate 72 and the protrusion 72-1 may be connected with each other to form an integral structure. In the present disclosure, by providing the recess of the first active connection line 10 and the protrusion 72-1 of the second plate 72, an area of the second plate 72 can be effectively increased, and a capacitance of the second storage capacitor can be effectively increased.

In an exemplary implementation, a plate connection line 72-2 is provided at a side of the second plate 72 in the first direction X or in a direction opposite to the first direction X. A first end of the plate connection line 72-2 is connected with the second plate 72 of this circuit unit, and a second end of the plate connection line 72-2 extends along the first direction X or in a reverse direction of the first direction X to connect with a second plate 72 of an adjacent circuit unit, such that second plates 72 of adjacent circuit units in a unit row are connected with each other. Because the second plate 72 is connected with a first power line formed later, the second plates 72 and the plate connection lines 72-2, which are in the integral structure, of the plurality of circuit units can be reused as a transverse power line extending along the first direction X, which not only ensures that a plurality of second plates 72 in a unit row are at a same potential, but also reduces a voltage drop of a first power supply signal, and is beneficial to improving the uniformity of the panel, avoiding the display defect of the display substrate and ensuring the display effect of the display substrate.

In an exemplary implementation, the plurality of second plates 72 and the plurality of plate connection lines 72-2 disposed at intervals along the first direction X may be connected with each other to form an integral structure.

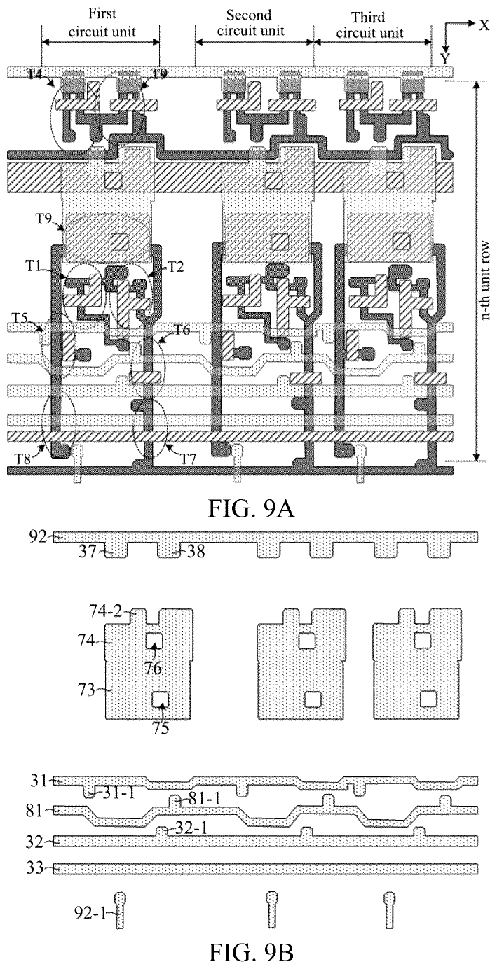

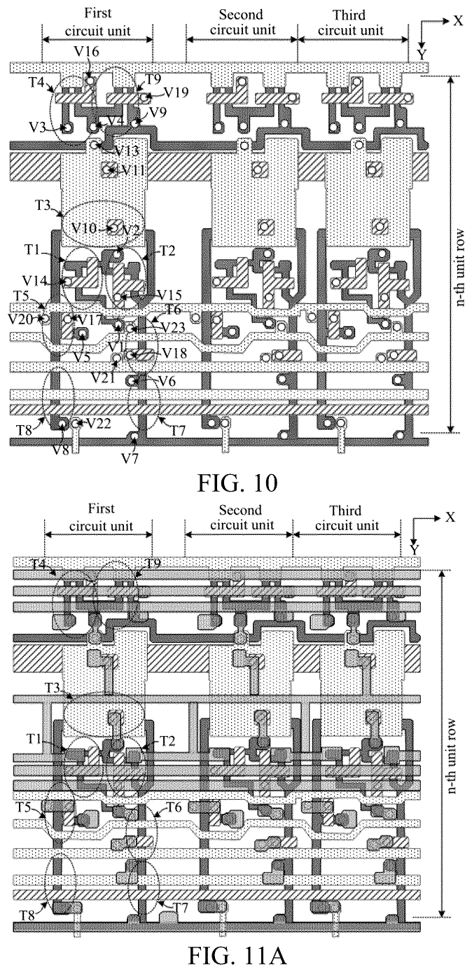

In an exemplary implementation, after the pattern of the first conductive layer is formed, a conductive processing may be performed on the semiconductor layer by using the first conductive layer as a shield, a region of the semiconductor layer shielded by the first conductive layer forms channel regions of the first to ninth transistors T1 to T9, and a region of the semiconductor layer not shielded by the first conductive layer is made to be conductive. That is, all of the first regions and the second regions of the first to ninth active layers, the first and second active connection lines are made to be conductive.
(13) A pattern of a second conductive layer is formed. In an exemplary implementation, forming the pattern of the second conductive layer may include: a third insulating thin film and a second conductive thin film are sequentially deposited on the substrate on which the aforementioned patterns are formed, and the second conductive thin film is patterned through a patterning process to form a third insulation layer that covers the first conductive layer and the pattern of the second conductive layer disposed on the third insulation layer, as shown in FIG. 9A and FIG. 9B, and FIG. 9B is a schematic diagram of the second conductive layer in FIG. 9A. In an exemplary implementation, the second conductive layer may be referred to as a second gate metal (GATE2) layer.

In an exemplary implementation, a pattern of a second conductive layer of each circuit unit in the display substrate includes, at least, a first light emitting signal line 31, a second light emitting signal line 32, a repair line 33, a second shield electrode 37, a third shield electrode 38, a third plate 73 of a first storage capacitor, a fourth plate 74 of a second storage capacitor, a first initial signal line 81, and a second reference signal line 92.

In an exemplary implementation, shapes of the first light emitting signal line 31, the second light emitting signal line 32, the repair line 33, the first initial signal line 81, and the second reference signal line 92 may be shapes of line in which a main portion extends along the first direction X, the first light emitting signal line 31, the second light emitting signal line 32, the repair line 33, and the first initial signal line 81 may be located between the first gate electrode 21 and the first scan signal line 61, and the second reference signal line 92 may be located on an opposite side of the fourth gate electrode 24 in the second direction Y.

In an exemplary implementation, the first light emitting signal line 31 may be located on a side of the first gate electrode 21 of the circuit unit in the second direction Y, the first initial signal line 81 may be located on a side of the first light emitting signal line 31 of the circuit unit in the second direction Y, the second light emitting signal line 32 may be located on a side of the first initial signal line 81 of the circuit unit in the second direction Y, and the repair line 33 may be located on a side of the second light emitting signal line 32 of the circuit unit in the second direction Y. That is, the second light emitting signal line 32 and the first initial signal line 81 may be located between the first light emitting signal line 31 and the repair line 33.

In an exemplary implementation, a first light emitting connection block 31-1 is provided on a side of the first light emitting signal line 31 close to the first initial signal line 81, the first light emitting connection block 31-1 may be provided in each circuit unit, a first end of the first light emitting connection block 31-1 is connected with the first light emitting signal line 31, a second end of the first light emitting connection block 31-1 extends in a direction to the first initial signal line 81, and the first light emitting connection block 31-1 is configured to connect to the fifth gate electrode 25 through the seventh connection electrode formed later.

In an exemplary implementation, the first light emitting signal line 31 and the plurality of first light emitting connection blocks 31-1 may be connected with each other to form an integral structure.

In an exemplary implementation, a second light emitting connection block 32-1 is provided on a side of the second light emitting signal line 32 close to the first initial signal line 81. The second light emitting connection block 32-1 may be disposed in each circuit unit, a first end of the second light emitting connection block 32-1 is connected with the second light emitting signal line 32, a second end of the second light emitting connection block 32-1 extends in a direction towards the first initial signal line 81, and the second light emitting connection block 32-1 is configured to connect to the sixth gate electrode 26 through an eighth connection electrode formed later.

In an exemplary implementation, the second initial signal line 32 and a plurality of light emitting connection blocks 32 may be connected with each other to form an integral structure.

In an exemplary implementation, a first initial connection block 81-1 is provided on a side of the first initial signal line 81 close to the first light emitting signal line 31. The first initial connection block 81-1 may be disposed in each circuit unit, a first end of the first initial connection block 81-1 is connected with the first initial signal line 81, a second end of the first initial connection block 81-1 extends in a direction towards the first light emitting signal line 31, and the first initial connection block 81-1 is configured to connect to the first region of the first active layer through a ninth connection electrode formed later.

In an exemplary implementation, the first initial signal line 81 and a plurality of first initial connection blocks 81-1 are connected with each other to form an integral structure.

In an exemplary implementation, a second reference connection block 92-1 is provided on a side of the second reference signal line 92 in the n-th unit row away from the second plate 72 in the n-th unit row. The second reference connection block 92-1 may be disposed in each circuit unit, a first end of the second reference connection block 92-1 is connected with the second reference signal line 92, and a second end of the second reference connection block 92-1 extends in a direction away from the second plate 72, that is, in a direction towards an (n−1)-th unit row. In an exemplary implementation, the second reference connection block 92-1 of the second reference signal line 92 in the n-th unit row is configured to connected to a first region of an eighth active layer in the (n−1)-th unit row through a sixth connection electrode formed later, so as to provide the second reference signal to a first electrode of the eighth transistor T8 in the (n−1)-th unit row.

In an exemplary implementation, the second initial signal line 92 and a plurality of second reference connection blocks 92-1 may be connected with each other to form an integral structure.

In an exemplary implementation, the second shield electrode 37 and the third shield electrode 38 may be in a rectangular shape, may be located on a side of the second reference signal line 92 close to the fourth plate 74, and may be disposed in each circuit unit. First ends of the second and third shield electrodes 37 and 38 are connected with the second reference signal line 92, and second ends of the second and third shield electrodes 37 and 38 extend in a direction to the fourth plate 74. An orthographic projection of the second shield electrode 37 on the substrate is overlapped, at least partially, with an orthographic projection of the fourth active layer between the two gate electrodes of the fourth transistor T4 in a circuit unit on the substrate, and an orthographic projection of the third shield electrode 38 on the substrate is overlapped, at least partially, with an orthographic projection of the ninth active layer between the two gate electrodes of the ninth transistor T9 in the circuit unit on the substrate. In an exemplary implementation, the second shield electrode 37 is configured to shield an influence of the data voltage jump on the fourth transistor T4, and the third shield electrode 38 is configured to shield an influence of the data voltage jump on the ninth transistor T9, so as to avoid the data voltage jump affecting the normal operation of the pixel drive circuit and improve the display effect.

In an exemplary implementation, a contour shape of the third plate 73 of the first storage capacitor may be a shape of rectangle of which corners may be chamfered, the third plate 73 of the first storage capacitor may be located between the first light emitting signal line 31 and the second reference signal line 92 in the circuit unit, an orthographic projection of the third plate 73 on the substrate is overlapped, at least partially, with an orthographic projection of the first plate 71 on the substrate, the third plate 73 may serve as an upper plate of the first storage capacitor, and the first plate 71 and the third plate 33 form the first storage capacitor of the pixel drive circuit.

In an exemplary implementation, a third plate 73 of each circuit unit is provided with a first opening 75. The first opening 75 may be located in a middle of the third plate 73, and the first opening 75 may be rectangular, such that the third plate 73 forms an annular structure. The first opening 75 exposes a third insulation layer covering the first plate 71, and an orthographic projection of the first plate 71 on the substrate contains an orthographic projection of the first opening 75 on the substrate. In an exemplary implementation, the first opening 75 is configured to accommodate a tenth via formed later, and the tenth via is located within the first opening 75 and exposes the first plate 71, so that a first connection electrode formed later is connected with the first plate 71.

In an exemplary implementation, a contour shape of the fourth plate 74 of the second storage capacitor may be a shape of rectangle, of which corners may be chamfered. The fourth plate 74 may be located between the third plate 73 and the second reference signal line 92 of the circuit unit, an orthographic projection of the fourth plate 74 on the substrate is overlapped, at least partially, with the orthographic projection of the second plate 72 on the substrate. The fourth plate 74 may serve as a lower plate of the second storage capacitor, and the second plate 72 and the fourth plate 74 form the second storage capacitor of the pixel drive circuit.

In an exemplary implementation, a fourth plate 74 of each circuit unit is provided with a second opening 76. The second opening 76 may be located in a middle of the fourth plate 74, and the second opening 76 may be rectangular, such that the fourth plate 74 forms an annular structure. The second opening 76 exposes a third insulation layer covering the second plate 72, and an orthographic projection of the second plate 72 on the substrate contains an orthographic projection of the second opening 76 on the substrate. In an exemplary implementation, the second opening 76 is configured to accommodate an eleventh via formed later, and the eleventh via is located within the second opening 76 and exposes the second plate 72, so that a first power supply connection line formed later is connected with the second plate 72.

In an exemplary implementation, a plate connection block 74-2 is provided on a side of the fourth plate 74 close to the second reference signal line 92, a shape of the plate connection block 74-2 may be “I” shaped, and the plate connection block 74-2 may be disposed in each circuit unit. In an exemplary implementation, a first end of the plate connection block 74-2 is connected with the fourth plate 74, a second end of the plate connection block 74-2 extends toward the second reference signal line 92, and the plate connection block 74-2 is configured to connect to a second region of the fourth active layer (i.e. a second region of the ninth active layer) through a second connection electrode formed later.

In an exemplary implementation, the fourth plate 74 and the third plate 73 may be connected with each other to form an integral structure. That is, the third plate 73 of the first storage capacitor and the fourth plate 74 of the second storage capacitor share a same plate.

In an exemplary implementation, the repair line 33 serves as a pre-set repair line, so that when a bright spot defect occurs in the display substrate, a signal is inputted to an anode of a sub-pixel where the bright spot defect occurs through the repair line 33 to repair the defective bright spot to a dark spot.
(14) A pattern of a fourth insulation layer is formed. In an exemplary implementation, forming the pattern of the fourth insulation layer may include: a fourth insulating thin film is deposited on the substrate on which the aforementioned patterns are formed, and the fourth insulating thin film is patterned through a patterning process, to form a fourth insulation layer that covers the second conductive layer, wherein a plurality of vias are disposed on each circuit unit, as shown in FIG. 10.

In an exemplary implementation, a plurality of vias of each circuit unit in the display substrate include, at least, a first via V1, a second via V2, a third via V3, a fourth via V4, a fifth via V5, a sixth via V6, a seventh via V7, an eighth via V8, a ninth via V9, a tenth via V10, an eleventh via V11, a thirteenth via V13, a fourteenth via V14, a fifteenth via V15, a sixteenth via V16, a seventeenth via V17, an eighteenth via V18, a nineteenth via V19, a twentieth via V20, a twenty-first via V21, a twenty-second via V22, and a twenty-third via V23.

In an exemplary implementation, an orthographic projection of the first via V1 on the substrate is within a range of an orthographic projection of the first region of the first active layer on the substrate. A fourth insulation layer, a third insulation layer and a second insulation layer within the first via V1 are etched away to expose a surface of the first region of the first active layer, and the first via V1 is configured such that the ninth connection electrode formed later is connected to the first region of the first active layer through the via.

In an exemplary implementation, an orthographic projection of the second via V2 on the substrate is within a range of an orthographic projection of the second region of the first active layer (i.e. the first region of the second active layer) on the substrate. A fourth insulation layer, a third insulation layer and a second insulation layer within the second via V2 are etched away to expose a surface of the second region of the first active layer (i.e. the first region of the second active layer), and the second via V2 is configured such that the first connection electrode formed later is connected to the second region of the first active layer (i.e. the first region of the second active layer) through this via.

In an exemplary implementation, an orthographic projection of the third via V3 on the substrate is within a range of an orthographic projection of the first region of the fourth active layer on the substrate. A fourth insulation layer, a third insulation layer and a second insulation layer within the third via V3 are etched away to expose a surface of the first region of the fourth active layer, and the third via V3 is configured such that a third connection electrode formed later is connected to the first region of the fourth active layer through the via V3.

In an exemplary implementation, an orthographic projection of the fourth via V4 on the substrate is within a range of an orthographic projection of the second region of the fourth active layer (i.e. the second region of the ninth active layer) on the substrate. A fourth insulation layer, a third insulation layer and a second insulation layer within the fourth via V4 are etched away to expose a surface of the second region of the fourth active layer (i.e. the second region of the ninth active layer), and the fourth via V4 is configured such that the second connection electrode formed later is connected to the second region of the fourth active layer (i.e. the second region of the ninth active layer) through this via.

In an exemplary implementation, an orthographic projection of the fifth via V5 on the substrate is within a range of an orthographic projection of the first region of the fifth active layer on the substrate. A fourth insulation layer, a third insulation layer and a second insulation layer within the fifth via V5 are etched away to expose a surface of the first region of the fifth active layer, and the fifth via V5 is configured such that a fourth connection electrode formed later is connected to the first region of the fifth active layer through the via.

In an exemplary implementation, an orthographic projection of the sixth via V6 on the substrate is within a range of an orthographic projection of the second region of the sixth active layer (i.e. the second region of the seventh active layer) on the substrate. A fourth insulation layer, a third insulation layer and a second insulation layer within the sixth via V6 are etched away to expose a surface of the second region of the sixth active layer (i.e. the second region of the seventh active layer), and the sixth via V6 is configured such that a fifth connection electrode formed later is connected to the second region of the sixth active layer (i.e. the second region of the seventh active layer) through the via V6.

In an exemplary implementation, an orthographic projection of the seventh via V7 on the substrate is within a range of an orthographic projection of the first region of the seventh active layer on the substrate. A fourth insulation layer, a third insulation layer, and a second insulation layer within the seventh via V7 are etched away to expose a surface of the first region of the seventh active layer, and the seventh via V7 is configured such that the second initial signal line formed later is connected to the first region of the seventh active layer through the via V7.

In an exemplary implementation, an orthographic projection of the eighth via V8 on the substrate is within a range of an orthographic projection of the first region of the eighth active layer on the substrate. A fourth insulation layer, a third insulation layer, and a second insulation layer within the eighth via V8 are etched away to expose a surface of the first region of the eighth active layer, and the eighth via V8 is configured such that the sixth connection electrode formed later is connected to the first region of the eighth active layer through the via V8.

In an exemplary implementation, an orthographic projection of the ninth via V9 on the substrate is within a range of an orthographic projection of the first region of the ninth active layer on the substrate. A fourth insulation layer, a third insulation layer, and a second insulation layer within the ninth via V9 are etched away to expose a surface of the first region of the ninth active layer, and the ninth via V9 is configured such that the first reference signal line formed later is connected to the first region of the ninth active layer through the via V9.

In an exemplary implementation, an orthographic projection of the tenth via V10 on the substrate is located within a range of an orthographic projection of the opening 75 of the third plate 73 on the substrate. A fourth insulation layer and a third insulation layer within the tenth via V10 are etched away to expose a surface of the first plate 71, and the tenth via V10 is configured such that the first connection electrode formed later is connected to the first plate 71 through the via V10.

In an exemplary implementation, an orthographic projection of the eleventh via V11 on the substrate is within a range of an orthographic projection of the second opening 76 of the fourth plate 74 on the substrate. A fourth insulation layer and a third insulation layer within the eleventh via V11 are etched away to expose a surface of the second plate 72, and the eleventh via V11 is configured such that the first power supply connection line formed later is connected to the second plate 72 through the via V11.

In an exemplary implementation, an orthographic projection of the thirteenth via V13 on the substrate is within a range of an orthographic projection of the fourth plate 74 on the substrate. A fourth insulation layer within the thirteenth via V13 is etched away to expose a surface of the fourth plate 74, and the thirteenth via V13 is configured such that the second connection electrode formed later is connected to the fourth plate 74 through the via V13.

In an exemplary implementation, an orthographic projection of the fourteenth via V14 on the substrate is within a range of an orthographic projection of the first gate electrode 21 on the substrate. A fourth insulation layer and a third insulation layer within the fourteenth via V14 are etched away to expose a surface of the first gate electrode 21, and the fourteenth via V14 is configured such that the fourth scan signal line formed later is connected to the first gate electrode 21 through the via V14.

In an exemplary implementation, an orthographic projection of the fifteenth via V15 on the substrate is within a range of an orthographic projection of the second gate electrode 22 on the substrate. A fourth insulation layer and a third insulation layer within the fifteenth via V15 are etched away to expose a surface of the second gate electrode 22, and the fifteenth via V15 is configured such that the fifth scan signal line formed later is connected to the second gate electrode 22 through the via V15.

In an exemplary implementation, an orthographic projection of the sixteenth via V16 on the substrate is within a range of an orthographic projection of the fourth gate electrode 24 on the substrate. A fourth insulation layer and a third insulation layer within the sixteenth via V16 are etched away to expose a surface of the fourth gate electrode 24, and the sixteenth via V16 is configured such that the third scan signal line formed later is connected to the fourth gate electrode 24 through the via V16.

In an exemplary implementation, an orthographic projection of the seventeenth via V17 on the substrate is within a range of an orthographic projection of the fifth gate electrode 25 on the substrate. A fourth insulation layer and a third insulation layer within the seventeenth via V17 are etched away to expose a surface of the fifth gate electrode 25, and the seventeenth via V17 is configured such that the seventh connection electrode formed later is connected to the fifth gate electrode 25 through the via V17.

In an exemplary implementation, an orthographic projection of the eighteenth via V18 on the substrate is within a range of an orthographic projection of the sixth gate electrode 26 on the substrate. A fourth insulation layer and a third insulation layer within the eighteenth via V18 are etched away to expose a surface of the sixth gate electrode 26, and the eighteenth via V18 is configured such that the eighteenth connection electrode formed later is connected to the sixth gate electrode 26 through the via V18.

In an exemplary implementation, an orthographic projection of the nineteenth via V19 on the substrate is within a range of an orthographic projection of the ninth gate electrode 29 on the substrate. A fourth insulation layer and a third insulation layer within the nineteenth via V19 are etched away to expose a surface of the ninth gate electrode 29, and the nineteenth via V19 is configured such that the second scan signal line formed later is connected to the ninth gate electrode 29 through the via V19.

In an exemplary implementation, an orthographic projection of the twentieth via V20 on the substrate is within an orthographic projection of the first light emitting connection block 31-1 of the first light emitting signal line 31 on the substrate. A fourth insulation layer within the twentieth via V20 is etched away to expose a surface of the first light emitting connection block 31-1, and the twentieth via V20 is configured such that the seventh connection electrode formed later is connected to the first light emitting connection block 31-1 through the via V20.

In an exemplary implementation, an orthographic projection of the twenty-first via V21 on the substrate is within an orthographic projection of the second light emitting connection block 32-1 of the second light emitting signal line 32 on the substrate. A fourth insulation layer within the twenty-first via V21 is etched away to expose a surface of the second light emitting connection block 32-1, and the twenty-first via V21 is configured such that the eighth connection electrode formed later is connected to the second light emitting connection block 32-1 through the via V21.

In an exemplary implementation, an orthographic projection of the twenty-second via V22 on the substrate is within a range of an orthographic projection of the second reference connection block 92-1 of the second reference signal line 92 on the substrate. A fourth insulation layer within the twenty-second via V22 is etched away to expose a surface of the second reference connection block 92-1, and the twenty-second via V22 is configured such that the sixth connection electrode formed later is connected to the second reference connection block 92-1 through the via V22.

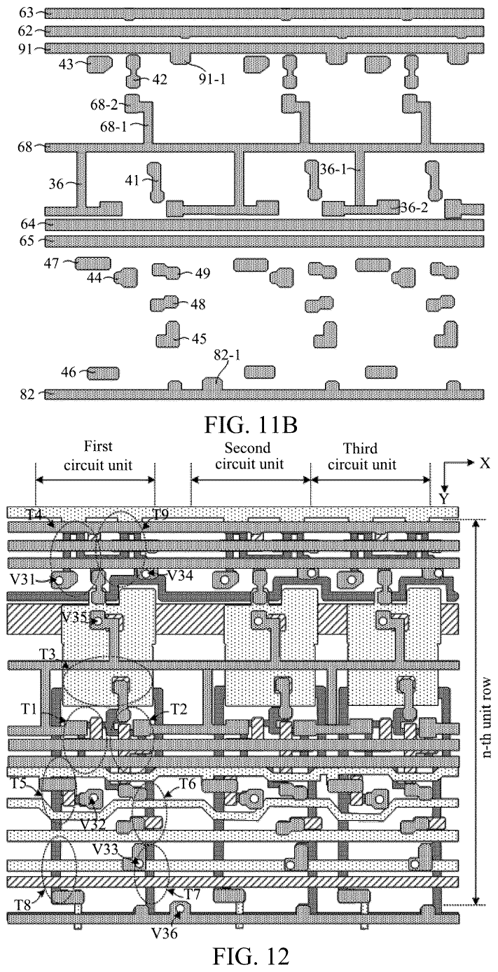

In an exemplary implementation, an orthographic projection of the twenty-third via V23 on the substrate is within an orthographic projection of the first initial connection block 81-1 of the first initial signal line 81 on the substrate. A fourth insulation layer within the twenty-third via V23 is etched away to expose a surface of the first initial connection block 81-1, and the twenty-third via V23 is configured such that the ninth connection electrode formed later is connected to the first initial connection block 81-1 through the via V23.
(15) A pattern of a third conductive layer is formed. In an exemplary implementation, forming the third conductive layer may include: a third conductive thin film is deposited on the substrate on which the aforementioned patterns are formed, the third conductive thin film is patterned through a patterning process to form the third conductive layer disposed on the fourth insulation layer, as shown in FIG. 11A and FIG. 11B, and FIG. 11B is a schematic diagram of the third conductive layer in FIG. 11A. In an exemplary implementation, the third conductive layer may be referred to as a first source-drain metal (SD1) layer.

In an exemplary implementation, each of patterns of third conductive layers of a plurality of circuit units in the display substrate may include a first shield electrode 36, a first connection electrode 41, a second connection electrode 42, a third connection electrode 43, a fourth connection electrode 44, a fifth connection electrode 45, a sixth connection electrode 46, a seventh connection electrode 47, an eighth connection electrode 48, a ninth connection electrode 49, a second scan signal line 62, a third scan signal line 63, a fourth scan signal line 64, a fifth scan signal line 65, a first power supply connection line 68, a second initial signal line 82, and a first reference signal line 91.

In an exemplary implementation, each of shapes of the second scan signal line 62, the third scan signal line 63, the fourth scan signal line 64, the fifth scan signal line 65, the first power supply connection line 68, the second initial signal line 82, and the first reference signal line 91 may be a shape of line in which a main portion extends along a first direction X. The second scan signal line 62, the third scan signal line 63, and the first reference signal line 91 may be located on a side of the fourth plate 74 in a direction opposite to the second direction Y. The fourth scan signal line 64, the fifth scan signal line 65, and the second initial signal line 82 may be located on a side of the third plate 73 in the second direction Y. The first power supply connection line 68 may be located in a region where the third plate 73 is located.

In an exemplary implementation, the first reference signal line 91 may be located on a side of the fourth plate 74 in a direction opposite to the second direction Y, the second scan signal line 62 may be located on a side of the first reference signal line 91 in a direction opposite to the second direction Y, and the third scan signal line 63 may be located on a side of the second scan signal line 62 in a direction opposite to the second direction Y.

In an exemplary implementation, the fourth scan signal line 64 may be located on a side of the third plate 73 in the second direction Y, the fifth scan signal line 65 may be located on a side of the fourth scan signal line 64 in the second direction Y, and the second initial signal line 82 may be located on a side of the fifth scan signal line 65 in the second direction Y.

In an exemplary implementation, the first power supply connection line 68 may be located between the fourth scan signal line 64 and the first reference signal line 91, an orthographic projection of the first power supply connection line 68 on the substrate may be overlapped, at least partially, with an orthographic projection of the third plate 73 on the substrate, and the first power supply connection line 68 is configured to connect with the first power line formed later to form a high-voltage power supply grid structure with a mesh communication structure in the display substrate.

In an exemplary implementation, the second scan signal line 62 is connected with a ninth gate electrode 29 in each circuit unit through the nineteenth via V19, thereby the second scan signal line 62 being connected to the ninth gate electrode 29 of the ninth transistor T9 is achieved, and the second scan signal line 62 can control turn-on and turn-off of the ninth transistor T9.

In an exemplary implementation, the fifth scan signal line 65 is connected with a second gate electrode 22 in each circuit unit through the fifteenth via V15, thereby the fifth scan signal line 65 being connected to the second gate electrode 22 of the second transistor T2 is achieved, and the fifth scan signal line 65 can control turn-on and turn-off of the second transistor T2.

In an exemplary implementation, the second scan signal line 62 and the fifth scan signal line 65 may be connected to a same gate drive circuit after extending to a bezel region, so as to achieve output of a same scan signal. That is, the second scan signal line 62 and the fifth scan signal line 65 output a same second scan signal.

In an exemplary implementation, the third scan signal line 63 is connected to a fourth gate electrode 24 in each circuit unit through the sixteenth via V16, thereby the third scan signal line 63 being connected to the fourth gate electrode 24 of the fourth transistor T4 is achieved, and the third scan signal line 63 can control turn-on and turn-off of the fourth transistor T4.

In an exemplary implementation, the fourth scan signal line 64 is connected to a first gate electrode 21 in each circuit unit through the fourteenth via V14, thereby the fourth scan signal line 64 being connected to the first gate electrode 21 of the first transistor T1 is achieved, and the fourth scan signal line 64 can control turn-on and turn-off of the first transistor T1.

In an exemplary implementation, the second initial signal line 82 is connected to a first region of a seventh active layer in each circuit unit through the seventh via V7, thereby the second initial signal line 82 being connected to the first electrode of the seventh transistor T7 is achieved, and the second initial signal line 82 can write the second initial signal to the first electrode of the seventh transistor T7.

In an exemplary implementation, a second initial connection block 82-1 is provided on a side of the second initial signal line 82 close to the fifth scan signal line 65, a first end of the second initial connection block 82-1 is connected to the second initial signal line 82, and a second end of the second initial connection block 82-1 extends in a direction towards the fifth scan signal line 65. In an exemplary implementation, the second initial connection block 82-1 is configured to connect to the initial connection line formed later.

In the exemplary implementation, because the second active connection line 20 of the semiconductor layer is directly connected with first regions of seventh active layers of a plurality of circuit units in a unit row, and the second initial signal line 82 of the third conductive layer is connected with the first regions of the seventh active layers of the plurality of circuit units in the unit row through a via, thus the second active connection line 20 and the second initial signal line 82 form a signal line with a double-layer structure, which not only ensures that the first regions of the seventh active layers in the unit row are at a same potential, but also reduces a resistance of the signal lines, reduces a voltage drop of the second initial signal, which is beneficial to improving the uniformity of the panel, avoiding the display defect of the display substrate, and ensuring the display effect of the display substrate.

In an exemplary implementation, the first reference signal line 91 is connected to a first region of a ninth active layer in each circuit unit through the ninth via V9, thereby the first reference signal line 91 being connected to the first electrode of the ninth transistor T9 is achieved, and the first reference signal line 91 can write the first reference signal to the first electrode of the ninth transistor T9.

In an exemplary implementation, a first reference connection block 91-1 is provided on a side of the first reference signal line 91 close to the first power supply connection line 68, a first end of the first reference connection block 91-1 is connected to the first reference signal line 91, a second end of the first reference connection block 91-1 extends in a direction towards the first power supply connection line 68, and the first reference connection block 91-1 is configured to connect to a reference signal connection line formed later.

In the exemplary implementation, because the first active connection line 10 of the semiconductor layer is directly connected with first regions of ninth active layers of a plurality of circuit units in a unit row, and the first reference signal line 91 of the third conductive layer is connected with the first regions of the ninth active layers of the plurality of circuit units in the unit row through a via, thus the first active connection line 10 and the first reference signal line 91 form a signal line with a double-layer structure, which not only ensures that the first regions of the plurality of ninth active layers in the unit row are at a same potential, but also reduces a resistance of the signal lines, reduces a voltage drop of the first reference signal, which is beneficial to improving the uniformity of the panel, avoiding the display defect of the display substrate, and ensuring the display effect of the display substrate.

In an exemplary implementation, the first power supply connection line 68 is connected to a second plate 72 in each circuit unit through the eleventh via V11, thereby the first power supply connection line 68 being connected to the second plate 72 is achieved. Because the first power supply connection line 68 is connected to the first power line formed later, the first power supply connection line 68 can write the first power supply signal to the lower plate of the second storage capacitor (a first end of the second storage capacitor).

In an exemplary implementation, a first power supply connection block 68-1 is provided on a side of the first power supply connection line 68 away from the fourth scan signal line 64. A first end of the first power supply connection block 68-1 is connected to the first power supply connection line 68, a second end of the first power supply connection block 68-1 extends in a direction away from the fourth scan signal line 64, and is connected to a second plate 72 in each circuit unit through the eleventh via V11.

In an exemplary implementation, a second end of the first power supply connection block 68-1 is further provided with a second power supply connection block 68-2 in a rectangular shape. The second power supply connection block 68-2 is configured to connect to the first power line formed later.

In an exemplary implementation, the first power supply connection line 68, the first power supply connection block 68-1 and the second power supply connection block 68-2 may be connected with each other to form an integral structure.

In an exemplary implementation, a shape of the first shield electrode 36 may be “T” shaped, the first shield electrode 36 may be located on a side of the first power supply connection line 68 close to the fourth scan signal line 64, and may be disposed in each circuit unit. The “T” shaped first shield electrode 36 may include a first extension section 36-1 and a first shield section 36-2, a first end of the first extension section 36-1 is connected to a first power supply connection line 68, and a second end of the first extension section 36-1 is connected to the first shield section 36-2 after extending toward the fourth scan signal line 64. A shape of the first shield section 36-2 may be a shape of strip extending along the first direction X. For a first shield end of the first shield section 36-2 located on a side of the first extension section 36-1 in first direction X, and a second shield end of the first shield section 36-2 located on a side of the first extension section 36-1 in a direction opposite to the first direction X, an orthographic projection of the first shield end on the substrate is overlapped, at least partially, with an orthographic projection of a first active layer between the two gate electrodes of the first transistor T1 in the circuit unit on the substrate, and an orthographic projection of the second shield end on the substrate is overlapped, at least partially, with an orthographic projection of a second active layer between two gate electrodes of a second transistor T2 in an adjacent circuit unit on the substrate. In an exemplary implementation, the first shield electrode 36 is configured to shield an influence of data voltage jump on the first transistor T1 and the second transistor T2, to avoid the data voltage jump affecting a normal operation of the pixel drive circuit, and to improve the display effect.

In an exemplary implementation, the first power supply connection line 68 and the first shield electrode 36 may be connected with each other to form an integral structure. By disposing the first shield electrode 36 in the third conductive layer and being integrated with the first power supply connection line 68, in combination with the third plate 73 and the fourth plate 74 being integrated as described above, a quantity of vias can be reduced, so that the main portion of the first power supply connection line 68 can be disposed to extend in the first direction X without bending due to keeping clear from vias, thus indirectly reducing a length of the first power supply connection line 68, and a line width of the first power supply connection line 68 can be set to be wider, which is beneficial to reducing a voltage drop of the first power supply signal in transmission.

In an exemplary implementation, a shape of the first connection electrode 41 may be a shape of strip in which the main portion extends along the second direction Y, and the first connection electrode 41 may be located between the fourth scan signal line 64 and the first power supply connection line 68. A first end of the first connection electrode 41 is connected to the second region of the first active layer (i.e. the first region of the second active layer) through the second via V2, and a second end of the first connection electrode 41 is connected to the first plate 71 through the tenth via V10. In an exemplary implementation, the first connection electrode 41 enables the second electrode of the first transistor T1, the first electrode of the second transistor T2, the gate electrode of the third transistor T3, and the first plate 71 of the first storage capacitor (i.e., the first end of the first storage capacitor) being at a same potential, and the first connection electrode 41 may serve as the first node N1 of the pixel drive circuit.

In an exemplary implementation, a shape of the second connection electrode 42 may be a shape of polyline in which the main portion extends along the second direction Y, and the second connection electrode 42 may be located between the first reference signal line 91 and the first power supply connection line 68. A first end of the second connection electrode 42 is connected to the second region of the fourth active layer (i.e. the second region of the ninth active layer) through the fourth via V4, and a second end of the second connection electrode 42 is connected to the fourth plate 74 through the thirteenth via V13. In an exemplary implementation, the second connection electrode 42 enables the second electrode of the fourth transistor T4, the second electrode of the ninth transistor T9, the third plate 73 of the first storage capacitor (i.e. the second end of the first storage capacitor) and the fourth plate 74 of the second storage capacitor (i.e. the second end of the second storage capacitor) being at a same potential, and the second connection electrode 42 may serve as the fifth node N5 of the pixel drive circuit.

In an exemplary implementation, a shape of the third connection electrode 43 may be rectangular, the third connection electrode 43 may be located between the first reference signal line 91 and the first power supply connection line 68, and the third connection electrode 43 is connected to the first region of the fourth active layer through the third via V3. In an exemplary implementation, the third connection electrode 43 may serve as the first electrode of the fourth transistor T4, and is configured to connect with a data signal line formed later.

In an exemplary implementation, a shape of the fourth connection electrode 44 may be rectangular, the fourth connection electrode 44 may be located between the fifth scan signal line 65 and the second initial signal line 82, and the fourth connection electrode 44 is connected to the first region of the fifth active layer through the fifth via V5. In an exemplary implementation, the fourth connection electrode 44 may serve as the first electrode of the fifth transistor T5, and is configured to connect to the first power line formed later.

In an exemplary implementation, a shape of the fifth connection electrode 45 may be “L” shaped, the fifth connection electrode 45 may be located between the fifth scan signal line 65 and the second initial signal line 82, and the fifth connection electrode 45 is connected to the second region of the sixth active layer (i.e. the second region of the seventh active layer) through the sixth via V6. In an exemplary implementation, the fifth connection electrode 45 may serve as the second electrode of the sixth transistor T6 and the second electrode of the seventh transistor T7, and the fifth connection electrode 45 is configured to connect with an anode connection electrode formed later.

In an exemplary implementation, a shape of the sixth connection electrode 46 may be a shape of strip in which the main portion extends along the first direction X, the sixth connection electrode 46 may be located between the fifth scan signal line 65 and the second initial signal line 82, a first end of the sixth connection electrode 46 is connected to the first region of the eighth active layer through the eighth via V8, and a second end of the sixth connection electrode 46 is connected to the second reference connection block 92-1 through the twenty-second via V22. In an exemplary implementation, the sixth connection electrode 46 may serve as the first electrode of the eighth transistor T8. Because the second reference connection block 92-1 is connected to the second reference signal line 92, the second reference signal line 92 being connected to the first electrode of the eighth transistor T8 is achieved, and the second reference signal line 92 in the n-th unit row may write the second reference signal to the first electrode of the eighth transistor T8 in the (n−1)-th unit row.

In an exemplary implementation, a shape of the seventh connection electrode 47 may be a shape of strip in which the main portion extends along the first direction X, and the seventh connection electrode 47 may be located between the fifth scan signal line 65 and the second initial signal line 82. A first end of the seventh connection electrode 47 is connected to the fifth gate electrode 25 through the seventeenth via V17, and a second end of the seventh connection electrode 47 is connected to the first light emitting connection block 31-1 through the twentieth via V20. Because the first light emitting connection block 31-1 is connected to the first light emitting signal line 31, the first light emitting signal line 31 being connected to the fifth gate electrode 25 of the fifth transistor T5 is achieved, and the first light emitting signal line 31 can control turn-on and turn-off of the fifth transistor T5.

In an exemplary implementation, a shape of the eighth connection electrode 48 may be a shape of strip in which the main portion extends along the first direction X, and the eighth connection electrode 48 may be located between the fifth scan signal line 65 and the second initial signal line 82. A first end of the eighth connection electrode 48 is connected to the sixth gate electrode 26 through the eighteenth via V18, and a second end of the eighth connection electrode 48 is connected to the second light emitting connection block 32-1 through the twenty-first via V21. Because the second light emitting connection block 32-1 is connected with the second light emitting signal line 32, the second light emitting signal line 32 being connected to the sixth gate electrode 26 of the sixth transistor T6 is achieved, and the second light emitting signal line 32 can control turn-on and turn-off of the sixth transistor T6.

In an exemplary implementation, a shape of the ninth connection electrode 49 may be a shape of strip in which the main portion extends along the first direction X, and the ninth connection electrode 49 may be located between the fifth scan signal line 65 and the second initial signal line 82. A first end of the ninth connection electrode 49 is connected to the first region of the first active layer through the first via V1, and a second end of the ninth connection electrode 49 is connected to the first initial connection block 81-1 through the twenty-third via V23. Because the first initial connection block 81-1 is connected to the first initial signal line 81, the first initial signal line 81 being connected to the first electrode of the first transistor T1 is achieved, and the first initial signal line 81 can write a first initial signal to the first electrode of the first transistor T1.

In an exemplary implementation, the first plate 71 of the first storage capacitor and the second plate 72 of the second storage capacitor are disposed in the first conductive layer, the first plate 71 is at a potential of the first node, and the second plate 72 is at a potential of the first power line. The third plate 73 of the first storage capacitor and the fourth plate 74 of the second storage capacitor are disposed in the second conductive layer, the third plate 73 and the fourth plate 74 are connected with each other to form an integral structure, and the fourth plate 74 is connected to the second electrode of the fourth transistor T4 and the second electrode of the ninth transistor T9 through the second connection electrode, so that the third plate 73 and the fourth plate 74 in the integral structure are at a potential of the fifth node, connection between the second end of the first storage capacitor and the second end of the second storage capacitor can be achieved without providing any via, which can effectively reduce a quantity of openings, which not only can save a space for disposing vias, is beneficial to simplifying the process, improving a resolution of the display substrate, but also can reduce an interval between plates in a same layer, increase areas of the first storage capacitor and the second storage capacitor, thereby improving a voltage stabilizing effect, and improving a yield of the display substrate.
(16) A pattern of a fifth insulation layer is formed. In an exemplary implementation, forming the pattern of the fifth insulation layer may include: a fifth insulating film is deposited on the substrate on which the aforementioned patterns are formed, the fifth insulating film is patterned through a patterning process to form a fifth insulation layer that covers the third conductive layer, wherein a plurality of vias are disposed on each circuit unit, as shown in FIG. 12.

In an exemplary implementation, the plurality of vias on each circuit unit in the display substrate includes, at least, a thirty-first via V31, a thirty-second via V32, a thirty-third via V33, a thirty-fourth via V34, and a thirty-fifth via V35.

In an exemplary implementation, an orthographic projection of the thirty-first via V31 on the substrate is located within a range of an orthographic projection of the third connection electrode 43 on the substrate, a fifth insulation layer in the thirty-first via V31 is removed to expose a surface of the third connection electrode 43, and the thirty-first via V31 is configured such that the data signal line formed later is connected to the third connection electrode 43 through the thirty-first via.

In an exemplary implementation, an orthographic projection of the thirty-second via V32 on the substrate is located within a range of an orthographic projection of the fourth connection electrode 44 on the substrate, a fifth insulation layer within the thirty-second via V32 is removed to expose a surface of the fourth connection electrode 44, and the thirty-second via V32 is configured such that the first power line formed later is connected to the fourth connection electrode 44 through the thirty-second via.

In an exemplary implementation, an orthographic projection of the thirty-third via V33 on the substrate is located within a range of an orthographic projection of the fifth connection electrode 45 on the substrate, a fifth insulation layer within the thirty-third via V33 is removed to expose a surface of the fifth connection electrode 45, and the thirty-third via V33 is configured such that the anode connection electrode formed later is connected to the fifth connection electrode 45 through the thirty-third via.

In an exemplary implementation, an orthographic projection of the thirty-fourth via V34 on the substrate is within a range of an orthographic projection of the first reference connection block 91-1 of the first reference signal line 91 on the substrate. A fifth insulation layer within the thirty-fourth via V34 is removed to expose a surface of the first reference connection block 91-1, and the thirty-fourth via V34 is configured such that the reference signal connection line formed later is connected to the first reference connection block 91-1 through the via V34.

In an exemplary implementation, an orthographic projection of the thirty-fifth via V35 on the substrate is within a range of an orthographic projection of the second power supply connection block 68-2 of the first power supply connection line 68 on the substrate, a fifth insulation layer within the thirty-fifth via V35 is removed to expose a surface of the second power supply connection block 68-2, and the thirty-fifth via V35 is configured such that the first power line formed subsequently is connected to the second power supply connection block 68-2 through the via V35.

In an exemplary implementation, at least one circuit unit may further include a thirty-sixth via V36. An orthographic projection of the thirty-sixth via V36 on the substrate is within a range of an orthographic projection of the second initial connection block 82-1 of the second initial signal line 82 on the substrate, a fifth insulation layer within the thirty-sixth via V36 is removed to expose a surface of the second initial connection block 82-1, and the thirty-sixth via V36 is configured such that a second initial connection line formed later is connected to the second initial connection block 82-1 through the via V36.

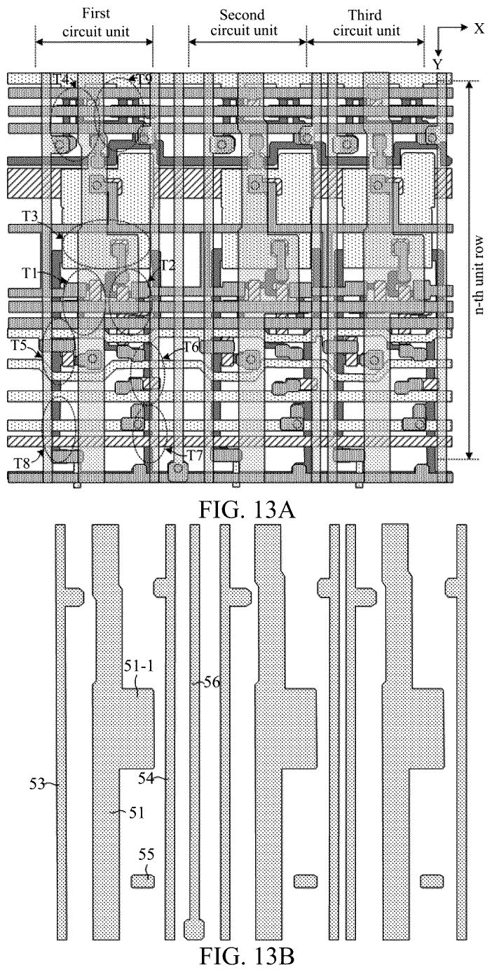

In an exemplary implementation, the thirty-sixth via V36 may be located between the first circuit unit and the second circuit unit.
(17) A pattern of a fourth conductive layer is formed. In an exemplary implementation, forming the pattern of the fourth conductive layer may include: a fourth conductive thin film is deposited on the substrate on which the aforementioned patterns are formed, the fourth conductive thin film is patterned through a patterning process to form the fourth conductive layer disposed on the fifth insulation layer, as shown in FIG. 13A and FIG. 13B, and FIG. 13B is a schematic diagram of the fourth conductive layer in FIG. 13A. In an exemplary implementation, the fourth conductive layer may be referred to as a second source-drain metal (SD2) layer.

In an exemplary implementation, each of patterns of fourth conductive layers of a plurality of circuit units in the display substrate may include a first power line 51, a data signal line 53, a reference signal connection line 54, and an anode connection electrode 55.

In an exemplary implementation, shapes of the first power line 51, the data signal line 53, and the reference signal connection line 54 may be a shape of strip in which a main portion extends along a second direction Y, the first power line 51 may be located on a side of the data signal line 53 in a first direction X, and the reference signal connection line 54 may be located on a side of the first power line 51 in the first direction X. That is, the first power line 51 may be located between the data signal line 53 and the reference signal connection line 54.

In an exemplary implementation, a shape of the first power supply line 51 may be a shape of bend line in which a main portion extending along the second direction Y. On one hand, the first power line 51 is connected to the fourth connection electrode 44 through the thirty-second via V32, and on the other hand, the first power supply line 51 is connected to the second power supply connection electrode 68-2 through the thirty-fifth via V35. Because the fourth connection electrode 44 is connected to the first region of the fifth active layer through the fifth via V5, writing of the first power supply signal to the first electrode of the fifth transistor T5 by the first power line 51 is achieved. Because the second power supply connection block 68-2 is connected with the first power supply connection block 68-1, and the first power supply connection block 68-1 is connected with the first power supply connection line 68, the first power supply connection line 68 in which the main portion extends along the first direction X and the first power line 51 in which the main portion extends along the second direction Y are connected with each other, so that the first power line 51 and the first power supply connection line 68 form a mesh structure for transmitting the first power supply signal in the display substrate, which can not only effectively reduce a resistance of the first power line 51 and reduce the voltage drop of the first power supply signal, but also effectively improve uniformity of the first power supply signal in the display substrate, effectively improve display uniformity and improve the display quality.

In an exemplary implementation, a power supply shield block 51-1 is provided on a side of the first power line 51 close to the reference signal connection line 54, a first end of the power supply shield block 51-1 is connected with the first power line 51, and a second end of the power supply shield block 51-1 extends in a direction towards the reference signal connection line 54. A shape of the power supply shield block 51-1 may be rectangular, and an orthographic projection of the power supply shield block 51-1 on the substrate is overlapped, at least partially, with the orthographic projection of the first connection electrode 41 on the substrate. Because the first connection electrode 41 serves as the first node N1 in the pixel drive circuit, the power supply shield block 51-1 which is at a constant voltage can effectively shield an influence of other signals in the pixel drive circuit on the first Node N1, thereby avoiding an influence of other signals (such as data voltage jump) on a potential at the first Node N1 in the pixel drive circuit, and improving the display effect.

In an exemplary implementation, the first power line 51 and the power supply shield block 51-1 may be connected with each other to form an integral structure.

In an exemplary implementation, the orthographic projection of the power supply shield block 51-1 on the substrate may include the orthographic projection of the first connection electrode 41 on the substrate.

In an exemplary implementation, the orthographic projection of the first power line 51 on the substrate is overlapped, at least partially, with the orthographic projection of the second connection electrode 42 on the substrate. Because the second connection electrode 42 serves as the fifth Node N5 in the pixel drive circuit, the first power line 51 which is at a constant voltage can effectively shield an influence of other signals in the pixel drive circuit on the fifth Node N5, thereby avoiding an influence of other signals on a potential at the fifth Node N5 in the pixel drive circuit, and improving the display effect.

In an exemplary implementation, the first power line 51 may be of an unequal width design, and the first power line 51 with the unequal width design can not only facilitate a layout of a pixel structure, but also reduce a parasitic capacitance between the first power line and a data signal line.

In an exemplary implementation, a shape of the data signal line 53 may be a shape of straight line in which a main portion extends along the second direction Y, and the data signal line 53 is connected with the third connection electrode 43 through the thirty-first via V31. Because the third connection electrode 43 is connected to the first region of the fourth active layer through the third via V3, writing of the data signal to the first electrode of the fourth transistor T4 by the data signal line 53 is achieved.

In an exemplary implementation, a shape of the reference signal connection line 54 may be a shape of straight line in which a main portion extends along the second direction Y, and the reference signal connection line 54 is connected to the first reference connection block 91-1 through the thirty-fourth via V34. Because the first reference connection block 91-1 is connected with the first reference signal line 91, the first reference signal line 91 in which the main portion extends along the first direction X and the reference signal connection line 54 in which the main portion extends along the second direction Y are connected with each other, so that the first reference signal line 91 and the reference signal connection line 54 form a mesh structure for transmitting the first reference signal in the display substrate, which can not only effectively reduce the resistance of the first reference signal line and reduce the voltage drop of the first reference signal, but also effectively improve uniformity of the first reference signal in the display substrate, effectively improve the display uniformity and improve the display quality.

In an exemplary implementation, a shape of the anode connection electrode 55 may be a rectangle, and the anode connection electrode 55 is connected with the fifth connection electrode 45 through the thirty-third via V33. Because the fifth connection electrode 45 is connected with the second region of the sixth active layer (i.e. the second region of the seventh active layer) through the sixth via V6, the anode connection electrode 55 being connected with the second electrode of the sixth transistor T6 and the second electrode of the seventh transistor

T7 is achieved. In an exemplary implementation, the anode connection electrode 55 is configured to connect with an anode formed subsequently, thereby the pixel drive circuit can drive a light emitting device.

In an exemplary implementation, at least one circuit unit may further include a second initial connection line 56. A shape of the second initial connection line 56 may be a straight line in which a main portion extends in the second direction Y, and the second initial connection line 56 is connected to the second initial connection block 82-1 through the thirty-sixth via V36. Because the second initial connection block 82-1 is connected with the second initial signal line 82, thus the second initial signal line 82 in which the main portion extends along the first direction X and the second initial connection line 56 in which the main portion extends along the second direction Y are connected with each other, so that the second initial signal line 82 and the second initial connection line 56 form a mesh structure for transmitting the second initial signal in the display substrate, which not only may effectively reduce the resistance of the second initial signal line and reduce the voltage drop of the second initial signal, but also may effectively improve the uniformity of the second initial signals in the display substrate, effectively improve the display uniformity and improve the display attribute and the display quality. In an exemplary implementation, the second initial connection line 56 may be located between the reference signal connection line 54 of the first circuit unit and the data signal line 53 of the second circuit unit.

In an exemplary implementation, the first power supply connection line 68 of the third conductive layer may be disposed in each unit row, and the first power line 51 of the fourth conductive layer may be disposed in each unit column, and a plurality of first power lines 51 are connected, respectively, to a plurality of first power supply connection lines 68 to form a mesh structure for transmitting the first power supply signal.

In an exemplary implementation, the first reference signal line 91 of the third conductive layer may be disposed in each unit row, the reference signal connection line 54 of the fourth conductive layer may be disposed in each unit column, and a plurality of first reference signal lines 91 are connected, respectively, to a plurality of reference signal connection lines 54 to form a mesh structure for transmitting the first reference signal.

In an exemplary implementation, the second initial signal line 82 of the third conductive layer may be disposed in each unit row, one of the second initial connection lines 56 of the fourth conductive layer may be disposed every two unit columns, and a plurality of second initial connection lines 56 are connected, respectively, with a plurality of second initial signal lines 82 to form a mesh structure for transmitting the second initial signal.

A subsequent manufacturing process may include forming a pattern of a first planarization layer, the first planarization layer is provided with a plurality of anode vias, orthographic projections of the anode vias on the substrate are within a range of an orthographic projection of the anode connection electrode on the substrate. A first planarization layer within the anode vias is removed to expose a surface of the anode connection electrode, and the anode vias are configured such that the anode formed later is connected to the anode connection electrode through the anode vias.

So far, the drive circuit layer in this embodiment is manufactured on the substrate. In a plane parallel to the display substrate, the drive circuit layer may include a plurality of circuit units, each of the circuit units may include a pixel drive circuit, and a first scan signal line, a second scan signal line, a third scan signal line, a fourth scan signal line, a fifth scan signal line, a first light emitting signal line, a second light emitting signal line, a first initial signal line, a second initial signal line, a first reference signal line, a second reference signal line, a first power line and a data signal line, which are connected with the pixel drive circuit. In a plane perpendicular to the display substrate, the drive circuit layer may include, at least, a first insulation layer, a semiconductor layer, a second insulation layer, a first conductive layer, a third insulation layer, a second conductive layer, a fourth insulation layer, a third conductive layer, a fifth insulation layer, and a fourth conductive layer, which are stacked sequentially on the substrate. The active layers of the first active connection line 10, the second active connection line 20, the first to ninth transistors T1 to T9 may be disposed in the semiconductor layer. The first gate electrode 21, the second gate electrode 22, the fourth gate electrode 24, the fifth gate electrode 25, the sixth gate electrode 26, the ninth gate electrode 29, the first scan signal line 61, the first plate 71, and the second plate 72 may be disposed in the first conductive layer. The first light emitting signal line 31, the second light emitting signal line 32, the repair line 33, the second shield electrode 37, the third shield electrode 38, the third plate 73, the fourth plate 74, the first initial signal line 81, and the second reference signal line 92 may be disposed in the second conductive layer. The first shield electrode 36, the first to ninth connection electrodes 41 to 49, the second scan signal line 62, the third scan signal line 63, the fourth scan signal line 64, the fifth scan signal line 65, the first power supply connection line 68, the second initial signal line 82, and the first reference signal line 91 may be disposed in the third conductive layer. The first power line 51, the data signal line 53, the reference signal connection line 54, the anode connection electrode 55, and the second initial connection line 56 may be disposed in the fourth conductive layer.

In an exemplary implementation, after the drive circuit layer is manufactured, a light emitting structure layer and an encapsulation structure layer may be sequentially manufactured on the drive circuit layer, which is not repeated herein.

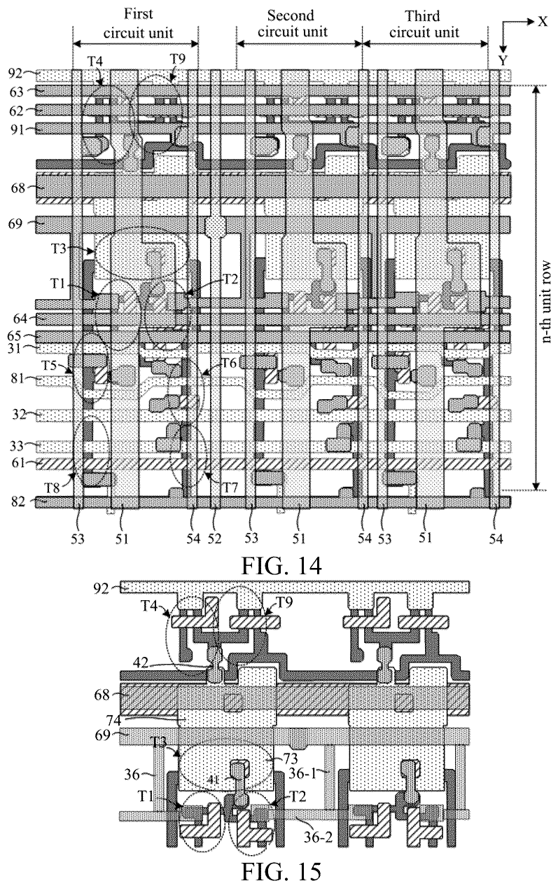

FIG. 14 is a schematic diagram of a planar structure of another display substrate according to an exemplary embodiment of the present disclosure, illustrating a structure of a pixel drive circuit in three circuit units (a first circuit unit, a second circuit unit, and a third circuit unit) in the display substrate. FIG. 15 is a schematic diagram of a structure in a region of a first storage capacitor and a second storage capacitor in FIG. 14. As shown in FIGS. 14 and 15, a main structure of the pixel drive circuit in the exemplary embodiment is substantially the same as the structure of the pixel drive circuit in the foregoing embodiment, except that a second power line and a second power supply connection line are provided in the present embodiment, and the second power supply connection line is connected with the first shield electrode.

As shown in FIG. 14, in an exemplary implementation, the display substrate may further include at least one second power line 52 extending along the second direction Y, and at least one second power supply connection line 69 extending along the first direction X. In an exemplary implementation, the second power line 52 is connected with cathodes of a plurality of light emitting units, and is configured to continuously supply a low-level signal to the cathodes. In an exemplary implementation, the second power line 52 extending along the second direction Y and the second power supply connection line 69 extending along the first direction X are connected with each other to form a mesh structure for transmitting a second power supply signal.

In an exemplary implementation, in a plane perpendicular to the display substrate, a drive circuit layer may include a semiconductor layer, a first conductive layer, a second conductive layer, a third conductive layer, and a fourth conductive layer that are sequentially provided on a substrate. The second power line 52 and the second power supply connection line 69 may be disposed in different conductive layers, and may be connected through a via.

In an exemplary implementation, the first shield electrode 36 and a second power supply connection line 69 may be disposed in a same layer, and formed synchronously through a same patterning process.

In an exemplary implementation, the second power supply connection line 69 may be disposed in the third conductive layer, and the second power line 52 may be disposed in the fourth conductive layer.

In conjunction with what is shown in FIGS. 14 and 15, in an exemplary implementation, an orthographic projection of the first power supply connection line 68 on the substrate is overlapped, at least partially, with an orthographic projection of the fourth plate 74 on the substrate, and an orthographic projection of the second power supply connection line 69 on the substrate is overlapped, at least partially, with an orthographic projection of the third plate 73 on the substrate.

In an exemplary implementation, the first shield electrode 36 may include a first extension section 36-1 and a first shield section 36-2. A shape of the first extension section 36-1 is a shape of strip extending along the second direction Y, and a shape of the first shield section 36-2 is a shape of strip extending along the first direction X. A first end of the first extension section 36-1 is connected with the second power supply connection line 69, and a second end of the first extension section 36-1 is connected with the first shield section 36-2. The first shield section 36-2 includes a first shield end and a second shield end, wherein an orthographic projection of the first shield end on the substrate is overlapped, at least partially, with an orthographic projection of a node between two gate electrodes of a first transistor T1 in a circuit unit on the substrate, and an orthographic projection of the second shield end on the substrate is overlapped, at least partially, with an orthographic projection of a node between two gate electrodes of a second transistor T2 in the adjacent circuit unit on the substrate.

In an exemplary implementation, the first shield electrode 36 and the second power supply connection line 69 are connected with each other to form an integral structure.

Positions and connection relationships in remaining structure are substantially the same as those in the foregoing embodiments, which is not repeated here.

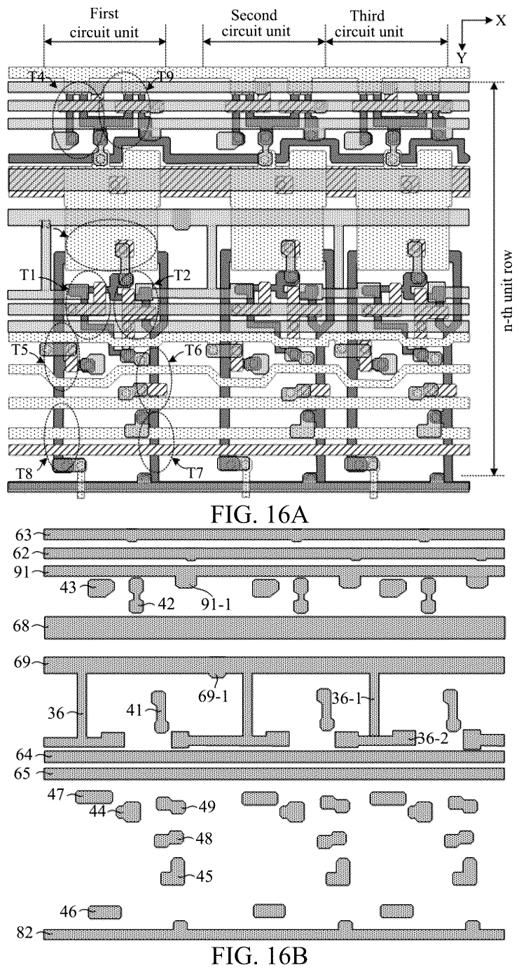

In an exemplary implementation, a manufacturing process for the display substrate in this embodiment may include following acts.
(21) Patterns of a first insulation layer, a semiconductor layer, a second insulation layer, a first conductive layer, a third insulation layer, a second conductive layer and a fourth insulation layer are formed sequentially. The semiconductor layer may include, at least, a first active layer 11 of a first transistor T1 to a ninth active layer 19 of a ninth transistor T9. The pattern of the first conductive layer includes, at least, a first gate electrode 21, a second gate electrode 22, a fourth gate electrode 24, a fifth gate electrode 25, a sixth gate electrode 26, a ninth gate electrode 29, a first scan signal line 61, a first plate 71 of a first storage capacitor and a second plate 72 of a second storage capacitor. The pattern of the second conductive layer includes, at least, a first light emitting signal line 31, a second light emitting signal line 32, a repair line 33, a second shield electrode 37, a third shield electrode 38, a third plate 73 of the first storage capacitor, a fourth plate 74 of the second storage capacitor and a second reference signal line 92. A plurality of vias in the fourth insulation layer include, at least, first to eleventh vias V1 to V11, and thirteenth to twenty-third vias V13 to V23. Positions, structures and connection relationships of the above-mentioned patterns are substantially the same as those in the foregoing embodiments, which is not repeated here.
(22) A pattern of a third conductive layer is formed. In an exemplary implementation, forming the pattern of the third conductive layer may include: a third conductive thin film is deposited on the substrate on which the aforementioned patterns are formed, the third conductive thin film is patterned through a patterning process to form the third conductive layer disposed on the fourth insulation layer, as shown in FIG. 16A and FIG. 16B, and FIG. 16B is a schematic diagram of the third conductive layer in FIG. 16A.

In an exemplary implementation, each of patterns of third conductive layers of a plurality of circuit units in the display substrate may include a first shield electrode 36, a first connection electrode 41, a second connection electrode 42, a third connection electrode 43, a fourth connection electrode 44, a fifth connection electrode 45, a sixth connection electrode 46, a seventh connection electrode 47, an eighth connection electrode 48, a ninth connection electrode 49, a second scan signal line 62, a third scan signal line 63, a fourth scan signal line 64, a fifth scan signal line 65, a first power supply connection line 68, a second power supply connection line 69, a second initial signal line 82, and a first reference signal line 91.

In an exemplary implementation, a difference between the pattern of the third conductive layer in this embodiment and that in the foregoing embodiments is the first shield electrode 36, the first power supply connection line 68, and the second power supply connection line 69. Positions, structures and connection relationships of remaining patterns are substantially the same as those in the foregoing embodiments, which is not repeated here.

In an exemplary implementation, the first power supply connection line 68 may be located above the fourth plate 74, an orthographic projection of the first power supply connection line 68 on the substrate is overlapped, at least partially, with an orthographic projection of the fourth plate 74 on the substrate, and the first power supply connection line 68 is configured to connect with the first power line formed later to form a high-voltage power supply grid structure with a mesh communication structure in the display substrate.

In an exemplary implementation, the first power supply connection line 68 is connected to a second plate 72 in each circuit unit through the eleventh via V11, thereby the first power supply connection line 68 being connected to the second plate 72 is achieved. Because the first power supply connection line 68 is connected to the first power line formed later, thus the first power supply connection line 68 can write the first power supply signal to the lower plate of the second storage capacitor (a first end of the second storage capacitor). In this embodiment, because the first power supply connection line 68 is disposed above the fourth plate 74, the first power supply connection line 68 can be directly connected to a second plate 72 in each circuit unit through the eleventh via V11. Therefore, in this embodiment, the first power supply connection block 68-1 and the second power supply connection block 68-2 in the foregoing embodiments can be removed, so as to simplify the structure of the first power supply connection line 68, enlarge a dimension of the first power supply connection line 68 along the second direction Y, which is beneficial to reducing the voltage drop of the first power supply connection line 68.

In an exemplary implementation, the second power supply connection line 69 may be located above the third plate 73, an orthographic projection of the second power supply connection line 69 on the substrate is overlapped, at least partially, with an orthographic projection of the third plate 73 on the substrate, and the second power supply connection line 69 is configured to connect with the second power line formed later to form a lower-voltage power supply grid structure with a mesh communication structure on the display substrate.

In an exemplary implementation, in at least one circuit unit, a third power supply connection block 69-1 is provided on a side of the second power supply connection line 69 away from the first power supply connection line 68. A first end of the third power supply connection block 69-1 is connected with the second power supply connection line 69, a second end of the third power supply connection block 69-1 extends in a direction away from the first power supply connection line 68, and the third power supply connection block 69-1 is configured to connect to the second power line formed later. In an exemplary implementation, the third power supply connection block 69-1 may be disposed between the first circuit unit and the second circuit unit.

In an exemplary implementation, a shape of the first shield electrode 36 may be “T” shaped, the first shield electrode 36 may be located on a side of the second power supply connection line 69 close to the fourth scan signal line 64, and may be disposed in each circuit unit. The “T” shaped first shield electrode 36 may include a first extension section 36-1 and a first shield section 36-2, a first end of the first extension section 36-1 is connected to the second power supply connection line 69, and a second end of the first extension section 36-1 is connected to the first shield section 36-2 after extending toward the fourth scan signal line 64. A shape of the first shield section 36-2 may be a shape of strip extending along the first direction X. For a first shield end of the first shield section 36-2 located on a side of the first extension section 36-1 in first direction X, and a second shield end of the first shield section 36-2 located on a side of the first extension section 36-1 in a direction opposite to the first direction X, an orthographic projection of the first shield end on the substrate is overlapped, at least partially, with an orthographic projection of a first active layer between the two gate electrodes of the first transistor T1 in the circuit unit on the substrate, and an orthographic projection of the second shield end on the substrate is overlapped, at least partially, with an orthographic projection of a second active layer between two gate electrodes of a second transistor T2 in an adjacent circuit unit on the substrate. In an exemplary implementation, the first shield electrode 36 is configured to shield an influence of data voltage jump on the first transistor T1 and the second transistor T2, to avoid the data voltage jump affecting a normal operation of the pixel drive circuit, and to improve the display effect.

In an exemplary implementation, the second power supply connection line 69 and the first shield electrode 36 may be connected with each other to form an integral structure.

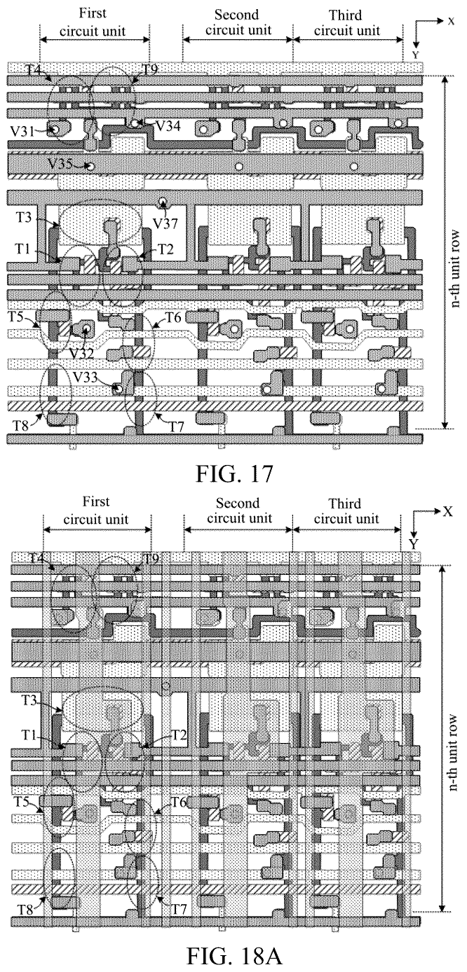

In this embodiment, by disposing the second power supply connection line 69 in the third conductive layer, the second power supply signal line extending along the first direction X on the display substrate is achieved, an area of the second power supply signal line on the display substrate is increased, which is beneficial to reducing the voltage drop of the second power supply signal in transmission.
(23) A pattern of a fifth insulation layer is formed. In an exemplary implementation, forming the pattern of the fifth insulation layer may include: a fifth insulating film is deposited on the substrate on which the aforementioned patterns are formed, the fifth insulating film is patterned through a patterning process to form a fifth insulation layer that covers the third conductive layer, wherein a plurality of vias are disposed on each circuit unit, as shown in FIG. 17.

In an exemplary implementation, the plurality of vias on each circuit unit in the display substrate includes, at least, a thirty-first via V31, a thirty-second via V32, a thirty-third via V33, a thirty-fourth via V34, and a thirty-fifth via V35. Positions, structures, and connection relationships of the thirty-first to thirty-fourth vias V31 to V34 are substantially the same as those in the foregoing embodiments, which is not be repeated here.

In an exemplary implementation, an orthographic projection of the thirty-fifth via V35 on the substrate is within a range of the orthographic projection of the first power supply connection line 68 on the substrate, a fifth insulation layer within the thirty-fifth via V35 is removed to expose a surface of the first power supply connection line 68, and the thirty-fifth via V35 is configured such that the first power line formed later is connected to the first power line 68 through the via V35.

In an exemplary implementation, at least one circuit unit may further include a thirty-seventh via V37, an orthographic projection of the thirty-seventh via V37 on the substrate is within a range of an orthographic projection of the third power supply connection block 69-1 of the second power supply connection line 69 on the substrate, a fifth insulation layer within the thirty-seventh via V37 is removed to expose a surface of the third power supply connection block 69-1, and the thirty-seventh via V37 is configured such that the second power line formed later is connected to the third power supply connection block 69-1 through the via V37.

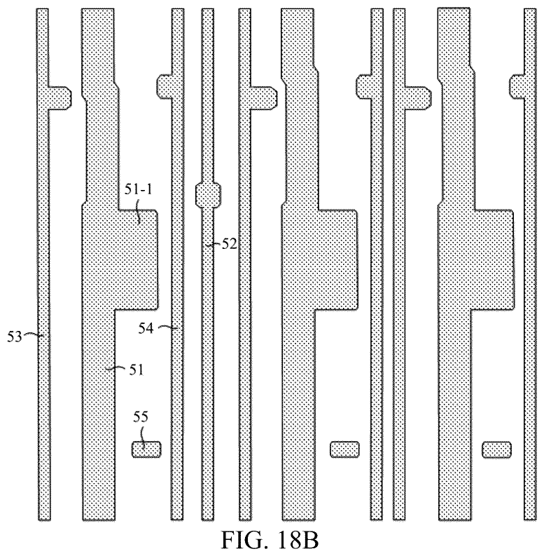

In an exemplary implementation, the thirty-seventh via V37 may be located between the first circuit unit and the second circuit unit.
(24) A pattern of a fourth conductive layer is formed. In an exemplary implementation, forming the pattern of the fourth conductive layer may include: a fourth conductive thin film is deposited on the substrate on which the aforementioned patterns are formed, the fourth conductive thin film is patterned through a patterning process to form the fourth conductive layer disposed on the fifth insulation layer, as shown in FIG. 18A and FIG. 18B, and FIG. 18B is a schematic diagram of the fourth conductive layer in FIG. 18A.

In an exemplary implementation, each of patterns of fourth conductive layers of a plurality of circuit units in the display substrate may include a first power line 51, a data signal line 53, a reference signal connection line 54, and an anode connection electrode 55. Positions, structures, and connection relationships of the patterns mentioned above are substantially the same as those in the foregoing embodiments, which is not repeated here.

In an exemplary implementation, at least one circuit unit may further include a second power line 52. A shape of the second power line 52 may be a straight line in which a main portion extends along the second direction Y, and the second power line 52 is connected to the third power connection block 69-1 through the thirty-seventh via V37, thus the second power connection line 69 in which the main portion extends along the first direction X and the second power connection line 52 in which the main portion extends along the second direction Y are connected with each other, so that the second power line 52 and the second power connection line 69 form a mesh structure for transmitting the second power signal in the display substrate, which can not only effectively reduce a resistance of the second power line 52 and reduce the voltage drop of the second power supply signal, but also effectively improve uniformity of the second power supply signal in the display substrate, effectively improve display uniformity and improve the display quality. In an exemplary implementation, the second power line 52 may be located between the first circuit unit and the second circuit unit.

In an exemplary embodiment, the second power supply connection line 69 of the third conductive layer may be disposed in each unit row, and one of the second power lines 52 of the fourth conductive layer may be disposed every two unit columns, and a plurality of the second power lines 52 are connected, respectively, to a plurality of the second power supply connection lines 69 to form a mesh structure for transmitting the second power supply signal. By adding the second power lines and the second power supply connection lines 69 on the display substrate, a space utilization rate of the display substrate is improved.

A subsequent manufacturing process may include forming a pattern of a first planarization layer, the first planarization layer is provided with a plurality of anode vias, orthographic projections of the anode vias on the substrate are within a range of an orthographic projection of the anode connection electrode 55 on the substrate. A first planarization layer within the anode vias is removed to expose a surface of the anode connection electrode 55, and the anode vias are configured such that the anode formed later is connected to the anode connection electrode 55 through the anode vias.

So far, the drive circuit layer in this embodiment is manufactured on the substrate. In an exemplary implementation, after the drive circuit layer is manufactured, a light emitting structure layer and an encapsulation structure layer may be sequentially manufactured on the drive circuit layer, which is not repeated here.

In an exemplary implementation, the substrate may be a flexible substrate, or a rigid substrate. The rigid base substrate may be made of, but is not limited to, one or more of glass and quartz. The flexible base substrate may be made of, but is not limited to, one or more of polyethylene terephthalate, ethylene terephthalate, polyether ether ketone, polystyrene, polycarbonate, polyarylate, polyarylester, polyimide, polyvinyl chloride, polyethylene, and textile fiber. In an exemplary implementation, the flexible substrate may include a first flexible material layer, a first inorganic material layer, a semiconductor layer, a second flexible material layer, and a second inorganic material layer which are stacked, wherein materials of the first flexible material layer and the second flexible material layer may be Polyimide (PI), Polyethylene Terephthalate (PET), or a surface-treated polymer soft film, or the like, materials of the first inorganic material layer and the second inorganic material layer may be Silicon Nitride (SiNx) or Silicon Oxide (SiOx), or the like, for improving a water and oxygen resistance capability of the substrate, and a material of the semiconductor layer may be amorphous silicon (a-si).

In an exemplary implementation, the first conductive layer, the second conductive layer, the third conductive layer, and the fourth conductive layer may be made of a metal material, such as any one or more of Argentum (Ag), Copper (Cu), Aluminum (Al), and Molybdenum (Mo), or an alloy material of the above metals, such as an Aluminum Neodymium alloy (AlNd) or a Molybdenum Niobium alloy (MoNb), and may be of a single-layer structure or a multi-layer composite structure, such as Mo/Cu/Mo. The first insulation layer, the second insulation layer, the third insulation layer, the fourth insulation layer, and the fifth insulation layer may be made of any one or more of Silicon Oxide (SiOx), Silicon Nitride (SiNx), and Silicon Oxynitride (SiON), and may be a single layer, a multi-layer, or a composite layer. The first insulation layer is referred to as a buffer layer, the second insulation layer and the third insulation layer are referred to as gate insulating (GI) layers, the fourth insulation layer is referred to as an interlayer dielectric (ILD) layer, and the fifth insulation layer is referred to as a passivation (PVX) layer. The first planarization layer may be made through an organic material such as resin. An active layer may be made of a material such as amorphous Indium Gallium Zinc Oxide (a-IGZO), Zinc Oxynitride (ZnON), Indium Zinc Tin Oxide (IZTO), amorphous Silicon (a-Si), poly-crystalline Silicon (p-Si), hexathiophene, or polythiophene. That is, the present disclosure is applicable to a transistor that is manufactured based on an oxide technology, a silicon technology, or an organic matter technology.

In a display substrate, a third plate of a first storage capacitor serves as a second end of the first storage capacitor, and a second plate of the second storage capacitor serves as a second end of the second storage capacitor, so that connection between the second plate and the third plate can be implemented by being punched, which not only reduces plate areas of the first storage capacitor and the second storage capacitor, but also has a problem of low space utilization rate of the display substrate. In addition, the line width of the first power supply connection line of the display substrate is small, so that the voltage drop of the first power supply signal is large.

In the embodiment of the present disclosure, the third plate of the first storage capacitor serves as the second end of the first storage capacitor, the fourth plate of the second storage capacitor serves as the second end of the second storage capacitor, and the third plate of the first storage capacitor and the fourth plate of the second storage capacitor are connected with each other to form the integral structure, so that connection between the second end of the first storage capacitor and the second end of the second storage capacitor can be achieved without providing any via, thereby effectively reducing a quantity of openings, which not only can save a space for a via, is beneficial to simplifying the process, and can improve a resolution of the display substrate, but also can reduce an interval between plates in a same layer, increase areas of the first storage capacitor and the second storage capacitor, thereby improving a voltage stabilizing effect at the first node N1 and the fifth node N5, and improving a yield of the display substrate.

In the embodiment of the present disclosure, by resetting a connection mode between the first storage capacitor and the second storage capacitor, the first power supply connection line is enabled to be extended along the first direction X and the line width to be set wider, thereby reducing the voltage drop of the first power supply signal and improving the display quality.

In the embodiment of the present disclosure, by providing the first power supply connection line in which the main portion extends along the first direction X and the first power line in which the main portion extends along the second direction Y, and the first power line and the first power supply connection line are connected with each other, so that the first power line and the first power supply connection line form the mesh structure for transmitting the first power supply signal on the display substrate, which can not only effectively reduce the resistance of the first power line and reduce the voltage drop of the first power supply signal, but also effectively improve the uniformity of the first power supply signal in the display substrate, effectively improve the display uniformity and improve the display quality.

In the embodiment of the present disclosure, by resetting the connection mode between the first storage capacitor and the second storage capacitor, and disposing the first power supply connection line above the second storage capacitor, the second power supply connection line can be disposed above the first storage capacitor, so that lines used for transmitting the second power supply signal are increased on the display substrate, the lines for transmitting the second power supply signal has larger area on the display substrate, effectively reducing the resistance of the second power line and reducing the voltage drop of the second power supply signal. Especially for a display substrate with a larger dimension, power consumption of the display substrate can be greatly reduced by reducing the voltage drop of the second power supply signal.

In an embodiment of the present disclosure, by providing the second power supply connection line in which the main portion extends along the first direction X and the second power line in which the main portion extends along the second direction Y, and the second power line and the second power supply connection line are connected with each other, so that the second power line and the second power supply connection line form a mesh structure for transmitting the second power supply signal on the display substrate, which can not only effectively reduce the resistance of the second power supply signal line and reduce the voltage drop of the second power supply signal, but also effectively improve the uniformity of the second power supply signal in the display substrate, effectively improve the display uniformity and the display quality.

In the embodiment of the present disclosure, by providing the first reference signal line in which the main portion extends along the first direction X and the reference signal connection line in which the main portion extends along the second direction Y, and the first reference signal line and the reference signal connection line are connected with each other, so that the first reference signal line and the reference signal connection line form the mesh structure for transmitting the first reference signal on the display substrate, which can not only effectively reduce the resistance of the first reference signal line and reduce the voltage drop of the first reference signal, but also effectively improve uniformity of the first reference signal in the display substrate, effectively improve the display uniformity and improve the display quality.

In the embodiment of the present disclosure, by providing the second initial signal line in which the main portion extends along the first direction X and the initial connection line in which the main portion extends along the second direction Y, and the second initial signal line and the initial connection line are connected with each other, so that the second initial signal line and the initial connection line form the mesh structure for transmitting the second initial signal on the display substrate, which not only may effectively reduce a resistance of a second initial signal line and reduce voltage drop of a second initial signal, but also may effectively improve uniformity of second initial signals in the display substrate, effectively improve display uniformity and improve display attribute and display quality.

In the embodiment of the present disclosure, by providing the first shield electrode, the second shield electrode and the third shield electrode, the influence of data voltage jump on the first transistor T1, the second transistor T2, the fourth transistor T4, the ninth transistor T9 and the fifth node N5 can be shielded, thus avoiding the influence of data voltage jump on the normal operation of the pixel drive circuit, and improving the display effect.

In the embodiment of the present disclosure, the power supply shield block is provided, the power supply shield block can effectively shield the influence of other signals in the pixel drive circuit on the first node N1, thus avoiding the influence of other signals on the potential at the first node N1 of the pixel drive circuit and improving the display effect.

The manufacturing process in the present disclosure may be compatible well with an existing manufacturing process, simple in process implementation, easy to implement, and has a high production efficiency, a low production cost, and a high yield.

The aforementioned structure shown in the present disclosure and the manufacturing process thereof are merely exemplary description. In an exemplary implementation, corresponding structures may be changed and patterning processes may be added or reduced according to actual needs, which is not limited here in the present disclosure.

In an exemplary implementation, the display substrate according to the present disclosure may be applied to a display apparatus with a pixel drive circuit, such as an OLED, a quantum dot display (QLED), a light emitting diode display (Micro LED or Mini LED), or a Quantum Dot Light Emitting Diode display (QDLED), which is not limited here in the present disclosure.

The present disclosure further provides a method for manufacturing a display substrate, for manufacturing the display substrate according to the foregoing embodiments.

In an exemplary implementation, the display substrate includes a plurality of circuit units, at least one circuit unit includes a pixel drive circuit, the pixel drive circuit includes, at least, a first storage capacitor and a second storage capacitor. The first storage capacitor includes at least two first capacitor plates, orthographic projections of the two first capacitor plates on the substrate are overlapped, at least partially, with each other, and the second storage capacitor includes at least two second capacitor plates, orthographic projections of the two second capacitor plates on the substrate are overlapped, at least partially, with each other. The method for manufacturing a display substrate may include:
forming a plurality of conductive layers on the substrate, one first capacitor plate in the first storage capacitor and one second capacitor plate in the second storage capacitor are disposed in a same conductive layer, the other first capacitor plate in the first storage capacitor and the other second capacitor plate in the second storage capacitor are disposed in a same conductive layer, and one of the first capacitor plate in the first storage capacitor and one of second capacitor plate in the second storage capacitor are connected with each other.

The present disclosure further provides a display apparatus which includes the aforementioned display substrate. The display apparatus may be any product or component with a display function, such as a mobile phone, a tablet computer, a television, a display, a laptop computer, a digital photo frame, or a navigator, which is not limited in the embodiments of the present invention.

Although implementations disclosed in the present disclosure are described as above, the described contents are only implementations which are used for facilitating understanding of the present disclosure, but are not intended to limit the present invention. Any skilled person in the art to which the present disclosure pertains may make any modification and variation in a form and details of implementation without departing from the spirit and scope of the present disclosure. However, the patent protection scope of the present invention should be subject to the scope defined in the appended claims.

1. A display substrate, comprising a plurality of circuit units, wherein:
at least one circuit unit comprises a pixel drive circuit, the pixel drive circuit comprises, at least, a first storage capacitor and a second storage capacitor, the first storage capacitor comprises at least two first capacitor plates, orthographic projections of the two first capacitor plates on a substrate are overlapped, at least partially, with each other, the second storage capacitor comprises at least two second capacitor plates, orthographic projections of the two second capacitor plates on the substrate are overlapped, at least partially, with each other; in a plane perpendicular to the display substrate, the display substrate comprises a plurality of conductive layers, a first capacitor plate in the first storage capacitor and a second capacitor plate in the second storage capacitor are disposed in a same conductive layer, another first capacitor plate in the first storage capacitor and another second capacitor plate in the second storage capacitor are disposed in a same conductive layer, and one of the first capacitor plates in the first storage capacitor and one of the second capacitor plates in the second storage capacitor are connected with each other.

2. The display substrate of claim 1, wherein: the plurality of conductive layers comprise, at least, a first conductive layer and a second conductive layer disposed sequentially on the substrate; the at least two first capacitor plates comprise a first plate disposed in the first conductive layer, and a third plate disposed in the second conductive layer, an orthographic projection of the first plate on the substrate is overlapped, at least partially, with an orthographic projection of the third plate on the substrate; the at least two second capacitor plates comprise a second plate disposed in the first conductive layer, a fourth plate disposed in the second conductive layer, an orthographic projection of the second plate on the substrate is overlapped, at least partially, with an orthographic projection of the fourth plate on the substrate, and the third plate is connected with the fourth plate.

3. The display substrate of claim 2, wherein the third plate of the first storage capacitor and the fourth plate of the second storage capacitor are connected with each other to form an integral structure.

4. The display substrate of claim 2, wherein: the pixel drive circuit further comprises a first initialization transistor, a compensation transistor, a data writing transistor, and a first reference transistor, which having a double gate structure, wherein a first electrode of the first initialization transistor is connected with a first initial signal line, a second electrode of the first initialization transistor is connected with a first electrode of the data writing transistor and the first plate, respectively, a first electrode of the data writing transistor is connected with the data signal line, a second electrode of the data writing transistor is connected with a second electrode of the first reference transistor, the third plate and the fourth plate, respectively, and a first electrode of the first reference transistor is connected with a first reference signal line.

5. The display substrate of claim 4, wherein: at least one circuit unit further comprises a first shield electrode whose orthographic projection on the substrate is overlapped, at least partially, with an orthographic projection of a node between two gate electrodes of the first initialization transistor on the substrate, and the orthographic projection of the first shield electrode on the substrate is overlapped, at least partially, with an orthographic projection of a node between two gate electrodes of the compensation transistor on the substrate.

6. The display substrate of claim 5, wherein: the display substrate further comprises at least one first power supply connection line extending along a first direction, and at least one first power line extending along a second direction, the first direction intersects with the second direction; the first power line and the first power supply connection line are disposed in different conductive layers, the first power line and the first power supply connection line are connected through a via to form a mesh structure for transmitting a first power supply signal, and the first shield electrode is connected with the first power supply connection line.

7. The display substrate of claim 6, wherein: the first shield electrode comprises a first extension section and a first shield section; a shape of the first extension section is a shape of strip extending along the second direction, and a shape of the first shield section is a shape of strip extending along the first direction; a first end of the first extension section is connected with the first power supply connection line, and a second end of the first extension section is connected with the first shield section; the first shield section comprises a first shield end and a second shield end, an orthographic projection of the first shield end on the substrate is overlapped, at least partially, with the orthographic projection of the node between the two gate electrodes of the first initialization transistor in the circuit unit on the substrate, and an orthographic projection of the second shield end on the substrate is overlapped, at least partially, with an orthographic projection of a node between two gate electrodes of a compensation transistor in an adjacent circuit unit on the substrate.

8. The display substrate of claim 6, wherein the first shield electrode and the first power supply connection line are connected with each other to form an integral structure.

9. The display substrate of claim 6, wherein an orthographic projection of the first power supply connection line on the substrate is overlapped, at least partially, with the orthographic projection of the fourth plate on the substrate.

10. The display substrate of claim 5, wherein: the display substrate further comprises at least one second power supply connection line extending along a first direction, and at least one second power line extending along a second direction, the first direction is intersected with the second direction; the second power line and the second power supply connection line are disposed in different conductive layers, the second power line and the second power supply connection line are connected through a via to form a mesh structure for transmitting a second power supply signal, and the first shield electrode is connected with the second power supply connection line.

11. The display substrate of claim 10, wherein: the first shield electrode comprises a first extension section and a first shield section; a shape of the first extension section is a shape of strip extending along the second direction, and a shape of the first shield section is a shape of strip extending along the first direction; a first end of the first extension section is connected with the second power supply connection line, and a second end of the first extension section is connected with the first shield section; the first shield section comprises a first shield end and a second shield end, an orthographic projection of the first shield end on the substrate is overlapped, at least partially, with the orthographic projection of the node between the two gate electrodes of the first initialization transistor in the circuit unit on the substrate, and an orthographic projection of the second shield end on the substrate is overlapped, at least partially, with an orthographic projection of a node between two gate electrodes of a compensation transistor in an adjacent circuit unit on the substrate.

12. The display substrate of claim 10, wherein the first shield electrode and the second power supply connection line are connected with each other to form an integral structure.

13. The display substrate of claim 10, wherein an orthographic projection of the second power supply connection line on the substrate is overlapped, at least partially, with the orthographic projection of the third plate on the substrate.

14. The display substrate of claim 4, wherein at least one circuit unit further comprises a second shield electrode, an orthographic projection of the second shield electrode on the substrate is overlapped, at least partially, with an orthographic projection of a node between two gate electrodes of the data writing transistor on the substrate.

15. The display substrate of claim 4, wherein at least one circuit unit further comprises a third shield electrode, an orthographic projection of the third shield electrode on the substrate is overlapped, at least partially, with an orthographic projection of a node between two gate electrodes of the first reference transistor on the substrate.

16. The display substrate of claim 1, wherein the display substrate further comprises at least one reference signal connection line extending along a first direction, and at least one reference signal line extending along a second direction, the first direction is intersected with the second direction; the reference signal line and the reference signal connection line are disposed in different conductive layers, and the reference signal connection line is connected with the reference signal line through a via to form a mesh structure for transmitting a reference signal.

17. The display substrate of claim 1, wherein the display substrate further comprises at least one initial signal line extending along a first direction and at least one initial connection line extending along a second direction, the first direction is intersected with the second direction; the initial signal line and the initial connection line are disposed in different conductive layers, and the initial connection line is connected with the initial signal line through a via to form a mesh structure for transmitting an initial signal.

18. A display apparatus, comprising the display substrate of claim 1.

19. A method for manufacturing a display substrate, wherein: the display substrate comprises a plurality of circuit units, at least one circuit unit comprises a pixel drive circuit, the pixel drive circuit comprises, at least, a first storage capacitor and a second storage capacitor; the first storage capacitor comprises at least two first capacitor plates, orthographic projections of the two first capacitor plates on the substrate are overlapped, at least partially, with each other, and the second storage capacitor comprises at least two second capacitor plates, orthographic projections of the two second capacitor plates on the substrate are overlapped, at least partially, with each other; and the method for manufacturing the display substrate comprises:
forming a plurality of conductive layers on the substrate, wherein: a first capacitor plate in the first storage capacitor and a second capacitor plate in the second storage capacitor are disposed in a same conductive layer, the other first capacitor plate in the first storage capacitor and the other second capacitor plate in the second storage capacitor are disposed in a same conductive layer, and one of the first capacitor plates in the first storage capacitor and one of the second capacitor plates in the second storage capacitor are connected with each other.

20. The display substrate of claim 2, wherein the display substrate further comprises at least one reference signal connection line extending along a first direction, and at least one reference signal line extending along a second direction, the first direction is intersected with the second direction; the reference signal line and the reference signal connection line are disposed in different conductive layers, and the reference signal connection line is connected with the reference signal line through a via to form a mesh structure for transmitting a reference signal.
